(19) United States
(12) Patent Application Publication
(10) Pub. No.: US 2017/0170268 A1
(43) Pub. Date: Jun. 15, 2017

(54) NANOWIRE METAL-OXIDE SEMICONDUCTOR (MOS) FIELD-EFFECT TRANSISTORS (FETs) (MOSFETs) EMPLOYING A NANOWIRE CHANNEL STRUCTURE HAVING ROUNDED NANOWIRE STRUCTURES

(71) Applicant: QUALCOMM Incorporated, San Diego, CA (US)

(72) Inventors: Stanley Seungchul Song, San Diego, CA (US); Peijie Feng, San Diego, CA (US); Kern Rim, San Diego, CA (US); Jeffrey Junhao Xu, San Diego, CA (US); Choh Fei Yeap, San Diego, CA (US)

(21) Appl. No.: 15/367,320

(22) Filed: Dec. 2, 2016

Related U.S. Application Data
(60) Provisional application No. 62/267,449, filed on Dec. 15, 2015.
(60) Provisional application No. 62/294,361, filed on Feb. 12, 2016.

(51) Int. Cl. H01L 29/06; H01L 21/324; H01L 27/088; H01L 21/02; H01L 29/78; H01L 29/66

(52) U.S. Cl. CPC H01L 29/0673; H01L 29/785; H01L 29/66795; H01L 29/0649; H01L 27/0886; H01L 21/02603; H01L 21/324

(57) ABSTRACT

Nanowire metal-oxide semiconductor (MOS) Field-Effect Transistors (FETs) (MOSFETs) employing a nanowire channel structure having rounded nanowire structures is disclosed. To reduce the distance between adjacent nanowire structures to reduce parasitic capacitance while providing sufficient gate control of the channel, the nanowire channel structure employs rounded nanowire structures. For example, the rounded nanowire structures provide for a decreased height from a center area of the rounded nanowire structures to end areas of the rounded nanowire structures. Gate material is disposed around rounded ends of the rounded nanowire structures to extend into a portion of separation areas between adjacent nanowire structures. The gate material extends in the separation areas between adjacent nanowire structures sufficient to create a fringing field to the channel where gate material is not adjacently disposed, to provide strong gate control of the channel even though gate material does not completely surround the rounded nanowire structures.

### PRIORITY APPLICATIONS

This patent application claims priority under 35 U.S.C. §119(e) to U.S. Provisional Patent Application Ser. No. 62/267,449 filed on Dec. 15, 2015 and entitled “NANOWIRE METAL-OXIDE SEMICONDUCTOR (MOS) FIELD-EFFECT TRANSISTORS (FETs) (MOSFETs) EMPLOYING A NANOWIRE CHANNEL STRUCTURE HAVING ROUNDED NANOWIRE STRUCTURES,” which is incorporated herein by reference in its entirety.

This patent application also claims priority under 35 U.S.C. §119(e) to U.S. Provisional Patent Application Ser. No. 62/294,361 filed on Feb. 12, 2016 and entitled “NANOWIRE METAL-OXIDE SEMICONDUCTOR (MOS) FIELD-EFFECT TRANSISTORS (FETs) (MOSFETs) EMPLOYING A NANOWIRE CHANNEL STRUCTURE HAVING ROUNDED NANOWIRE STRUCTURES,” which is incorporated herein by reference in its entirety.

### BACKGROUND

I. Field of the Disclosure

The technology of the disclosure relates generally to metal-oxide semiconductor (MOS) Field-Effect Transistors (FETs) (MOSFETs), and more particularly to the use of nanowire channels (e.g., silicon nanowires) in MOSFETs for short channel control.

II. Background

Transistors are essential components in modern electronic devices. Large numbers of transistors are employed in integrated circuits (ICs) in many modern electronic devices. For example, components such as central processing units (CPUs) and memory systems each employ a large quantity of transistors for logic circuits and memory devices.

As electronic devices become more complex in functionality, so does the need to include a greater number of transistors in such devices. But as electronic devices are required to be provided in increasingly smaller packages, such as in mobile devices for example, there is need to provide a greater number of transistors in a smaller IC chip. This increase in the number of transistors is achieved in part through continued efforts to miniaturize transistors in ICs (i.e., placing increasingly more transistors into the same amount of space). In particular, node sizes in ICs are being scaled down by a reduction in minimum metal line width in the ICs (e.g., 65 nanometers (nm), 45 nm, 28 nm, 20 nm, etc.). As a result, the gate lengths of planar transistors are also scalably reduced, thereby reducing the channel length of the transistors and interconnects. Reduced channel length in planar transistors has the benefits of increasing drive strength (i.e., increased drain current) with smaller parasitic capacitances resulting in reduced circuit delay. However, as channel length in planar transistors is reduced such that the channel length is of the same order of magnitude as the depletion layers widths, short channel effects (SCEs) can occur that degrade performance. More specifically, SCEs in planar transistors can cause increased current leakage, reduced threshold voltage, and/or threshold voltage roll-off (i.e., reduced threshold voltage at shorter gate lengths).

In this regard, to address the need to scale down channel lengths in transistors while avoiding or mitigating the effect of SCEs, alternative transistor designs to planar transistors have been developed. For example, a FinFET has been developed that provides a conducting channel wrapped by a thin silicon “Fin,” which forms the gate of the device. In this regard, FIG. 1A illustrates an exemplary FinFET 100. The FinFET 100 includes a body 102 (e.g., an oxide layer), The FinFET 100 includes a source 104 and a drain 106 interconnected by a Fin 108 that includes a conduction channel 110 (“channel 110”), as shown in FIG. 1B. The Fin 108 is surrounded by a “wrap-around” metal gate 112 (“gate 112”). FIG. 1B illustrates a close-up cross-section side view of the FinFET 100 in FIG. 1A along the A-A line. As shown in FIG. 1B, an interfacial layer 114 and dielectric material layer 116 are disposed around the channel 110 to insulate the gate 112 from the channel 110. The wrap-around structure of the gate 112 around the channel 110 provides better electrical control over the channel 110, and thus assists in reducing the leakage current and overcoming other SCEs. The thickness DFin of the Fin 108 (measured in the direction from the source 104 to the drain 106) determines the effective channel length of the FinFET 100.

Even with the advancement of FinFET designs, there still may be a need to improve transistor performance. For example, to reduce FinFET device delay, the thickness of the Fin can be reduced. However, reduction of the Fin reduces the effective channel length and may not result in the desired frequency performance, such as for radio-frequency (RF) applications. Further, as FinFETs are miniaturized, it may be difficult to retain the current metal pitch to Fin pitch ratios while still meeting other process and design criteria, such as cost effective Fin and metal patterning processes, metal width, metal space, and Fin height, and the like. Accordingly, there is a need to design smaller FinFETs that avoid these issues.

### SUMMARY OF THE DISCLOSURE

Aspects of the present disclosure involve nanowire metal-oxide semiconductor (MOS) Field-Effect Transistors (FETs) (MOSFETs) employing a nanowire channel structure having rounded nanowire structures. The use of a nanowire channel structure provides for an effective smaller channel length for a given drive strength with strong gate control of the channel to reduce leakage current. Reducing the distance between adjacent nanowire channel structures in a nanowire MOSFET reduces parasitic capacitances, thereby reducing delay of the nanowire MOSFET and/or increasing frequency performance. However, there is a minimum distance required between adjacent nanowire channel structures due to fabrication limitations to allow gate material to be disposed to surround the nanowire structures to provide sufficient gate control of the channel. In this regard, to allow the separation distance between adjacent nanowire structures to be reduced to further reduce parasitic capacitance while providing sufficient gate control of the channel, the nanowire channel structure employs rounded nanowire structures. For example, the rounded nanowire structures provide for a decreased height moving from a center area of the rounded nanowire structures to end portions of the rounded nanowire structures. Gate material is disposed around rounded end portions of the rounded nanowire structures to extend into at least a portion of the separation area between the adjacent rounded nanowire structures. The gate material may not completely surround the adjacent rounded nanowire structures. The gate material extends in the separation area between the adjacent nanowire rounded structures sufficient to create a fringing field to the channel where gate material is not adjacently disposed, to still provide strong gate control of the channel even though the gate material does not completely surround the rounded nanowire structures.

Note that the rounded nanowire structures provided in nanowire channel structures in MOSFETs disclosed herein can be provided in any form of nanowire. For example, the rounded nanowire channel structures can be provided as rounded nanowires, nanoslabs, and/or nanosheets. As another example, the rounded nanowire channel structures can also be provided in the form of rounded nanowire structures that have substantially the same width axis in an orthogonal axis in a cross-section of the rounded nanowire channel structures. As another example, the rounded nanowire channel structures can also be provided in the form of rounded nanoslabs that are elongated in an axis from an orthogonal axis in a cross-section of the rounded nanoslabs to increase the width of the nanowire channel structure to further increase drive strength and further reduce parasitic capacitance for further enhanced frequency performance. As another example, the rounded nanowire channel structures can also be provided in the form of rounded nanosheets that are substantially elongated in an axis from an orthogonal axis in a cross-section of the rounded nanosheets to increase the width of the rounded nanowire channel structures to further increase drive strength and further reduce parasitic capacitance for further enhanced frequency performance.

In this regard in one aspect, a nanowire MOSFET is provided. The nanowire MOSFET comprises a substrate. The nanowire MOSFET also comprises a channel body disposed on the substrate. The channel body comprises a channel comprising a nanowire channel structure comprising a plurality of rounded nanowire structures in a stack arrangement, each of the plurality of rounded nanowire structures comprising rounded end portions and a center portion disposed between the rounded end portions. The center portion has a greater height than the rounded end portions to form a plurality of separation areas each disposed between adjacent rounded nanowire structures among the plurality of rounded nanowire structures. The channel body also comprises at least one dielectric material layer disposed adjacent to the plurality of rounded nanowire structures and extending into a portion of each of the plurality of separation areas disposed between the adjacent rounded nanowire structures among the plurality of rounded nanowire structures. The channel body also comprises a gate material adjacent to the at least one dielectric material layer and extending into a portion of each of the plurality of separation areas disposed between the adjacent rounded nanowire structures among the plurality of rounded nanowire structures such that the gate material does not completely surround the plurality of rounded nanowire structures.

In another aspect, a nanowire MOSFET is provided. The nanowire MOSFET comprises a means for providing a channel body. The means for providing the channel body comprises a means for providing a channel comprising a means for providing a plurality of rounded nanowire structure in a stacked arrangement. Each of the means for providing the plurality of rounded nanowire structures comprises rounded end portions and a center portion disposed between the rounded end portions. The center portion has a greater height than the rounded end portions to form a plurality of separation areas each disposed between adjacent rounded nanowire structures among the plurality of rounded nanowire structures. The means for providing the channel body further comprises a means for providing a dielectric material layer adjacent to the means for providing the plurality of rounded nanowire structures. The means for providing the dielectric material layer extends into a portion of each of the plurality of separation areas. The means for providing the channel body also comprises a means for controlling the means for providing the channel disposed adjacent to the means for providing the dielectric materials layer, and extending into a portion of each of the plurality of separation areas and not completely surrounding the means for providing the plurality of rounded nanowire structures.

In another aspect, a method of fabricating a nanowire MOSFET is provided. The method comprises fabricating a plurality of nanowire structures in a channel body above a substrate in a stacked arrangement. The method also comprises annealing the plurality of nanowire structures to form a plurality of rounded nanowire structures forming a channel, the plurality of rounded nanowire structures creating the channel in the channel body and comprising rounded end portions and a center portion disposed between the rounded end portions. The center portion has a greater height than the rounded end portions forming a plurality of separation areas each disposed between adjacent rounded nanowire structures among the plurality of rounded nanowire structures. The method further comprises disposing at least one dielectric material layer adjacent to the plurality of rounded nanowire structures and extending into a portion of each of the plurality of separation areas disposed between the adjacent rounded nanowire structures among the plurality of rounded nanowire structures. The method also comprises disposing a gate material adjacent to the at least one dielectric material layer and extending into a portion of each of the plurality of separation areas disposed between the adjacent rounded nanowire structures among the plurality of rounded nanowire structures.

### BRIEF DESCRIPTION OF THE FIGURES

FIG. 1A illustrates an exemplary Fin Field-Effect Transistor (FET) (FinFET);

FIG. 1B is a close-up cross-section side view of the Fin in the FinFET in FIG. 1A along the A-A line;

FIG. 2 illustrates an exemplary nanowire metal-oxide semiconductor (MOS) FET (MOSFET);

FIG. 3 illustrates a close-up, side view of the channel body in the nanowire MOSFET in FIG. 2;

FIG. 4 illustrates an exemplary nanowire MOSFET employing a channel body employing a nanowire channel structure that employs rounded nanoslabs elongated in a horizontal dimension (i.e., along the X-axis) to allow the nanowire structures to be fabricated closer together to further reduce parasitic capacitance to reduce device delay and improved frequency performance;

FIGS. 5 and 6 illustrate an exemplary process of fabricating the channel body employing the rounded nanowire structures in FIG. 4;

FIG. 7 is an exemplary channel body for a nanowire MOSFET, wherein the channel body includes a nanowire channel structure employing rounded nanowires;

FIG. 8 is an exemplary channel body for a nanowire MOSFET, wherein the channel body includes a nanowire channel structure employing rounded nanoslab structures elongated in a vertical dimension (i.e., along the Y-axis);

FIGS. 9A and 9B illustrate an exemplary channel body for a nanowire MOSFET, wherein the channel body employs an alternative rounded nanowire channel structure employing contacted rounded nanoslabs elongated in a horizontal dimension (i.e., along the X-axis), and an exemplary process of fabricating the channel body;

FIG. 10 is another exemplary alternative channel body for a nanowire MOSFET, wherein the channel body includes a nanowire channel structure employing contacted rounded nanoslabs elongated in a vertical dimension (i.e., along the Y-axis);

FIG. 11 is another exemplary alternative channel body for a nanowire MOSFET, wherein the channel body includes a nanowire channel structure employing contacted rounded nanowire structures;

FIG. 12A illustrates a cross-section of an exemplary bulk Silicon (Si) body with etched comb structures rounded after the application of hydrogen (H₂) annealing;

FIG. 12B illustrates a cross-section of an exemplary silicon-on-insulator (SOI) that includes a Silicon Oxide (SiO₂) body with Si comb structures rounded after the application of hydrogen annealing;

FIG. 13 is a graph illustrating an exemplary radius of curvature formed on the corners of a Si structure from Hydrogen (H₂) annealing as a function of temperature;

FIGS. 14A and 14B are graphs illustrating an exemplary surface diffusion coefficient of a Hydrogen (H₂) annealed Si structure as a function of temperature and pressure, respectively;

FIG. 15 is a graph illustrating exemplary corner radiuses of a Hydrogen (H₂) annealed Si structure as a function of temperature and annealing time;

FIG. 16 is a block diagram of an exemplary processor-based system that can include nanowire MOSFETs having a nanowire channel structure employing rounded nanowire structures, including but not limited to the rounded nanowire structures illustrated in FIGS. 4-11; and

FIG. 17 is a block diagram of an exemplary wireless communications device that includes radio-frequency (RF) components formed in an integrated circuit (IC), wherein the RF components can include nanowire MOSFETs having a nanowire channel structure employing rounded nanowire structures, including but not limited to the rounded nanowire structures illustrated in FIGS. 4-11.

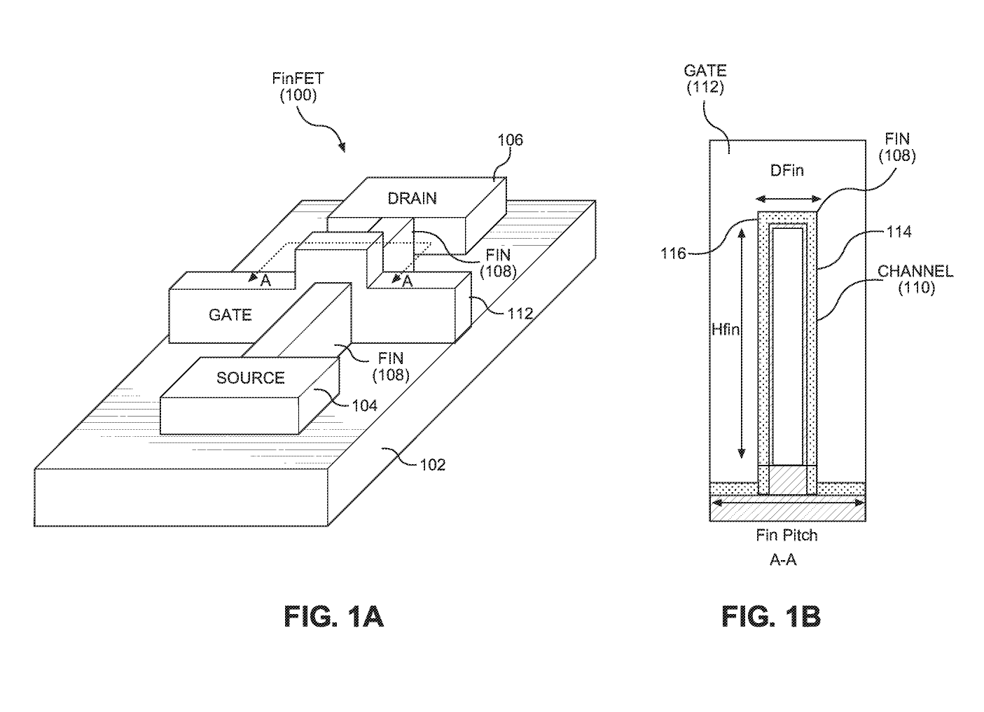

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects of the present disclosure involve nanowire metal-oxide semiconductor (MOS) Field-Effect Transistors (FETs) (MOSFETs) employing a nanowire channel structure having rounded nanowire structures. The use of a nanowire channel structure provides for an effective smaller channel length for a given drive strength with strong gate control of the channel to reduce leakage current. Reducing the distance between adjacent nanowire channel structures in a nanowire MOSFET reduces parasitic capacitances, thereby reducing delay of the nanowire MOSFET and/or increasing frequency performance. However, there is a minimum distance required between adjacent nanowire channel structures due to fabrication limitations to allow gate material to be disposed to surround the nanowire structures to provide sufficient gate control of the channel. In this regard, to allow the separation distance between adjacent nanowire structures to be reduced to further reduce parasitic capacitance while providing sufficient gate control of the channel, the nanowire channel structure employs rounded nanowire structures. For example, the rounded nanowire structures provide for a decreased height moving from a center area of the rounded nanowire structures to end portions of the rounded nanowire structures. Gate material is disposed around rounded end portions of the rounded nanowire structures to extend into at least a portion of the separation area between the adjacent rounded nanowire structures. The gate material may not completely surround the adjacent rounded nanowire structures. The gate material extends in the separation area between the adjacent nanowire rounded structures sufficient to create a fringing field to the channel where gate material is not adjacently disposed, to still provide strong gate control of the channel even though the gate material does not completely surround the rounded nanowire structures. Note that the rounded nanowire structures provided in nanowire channel structures in MOSFETs disclosed herein can be provided in any form of nanowire. For example, the rounded nanowire channel structures can be provided as rounded nanowires, nanoslabs, and/or nanosheets. As another example, the rounded nanowire channel structures can also be provided in the form of rounded nanowire structures that have substantially the same width axis in an orthogonal axis in a cross-section of the rounded nanowire channel structures. As another example, the rounded nanowire channel structures can also be provided in the form of rounded nanoslabs that are elongated in an axis from an orthogonal axis in a cross-section of the rounded nanoslabs to increase the width of the nanowire channel structure to further increase drive strength and further reduce parasitic capacitance for further enhanced frequency performance. As another example, the rounded nanowire channel structures can also be provided in the form of rounded nanosheets that are substantially elongated in an axis from an orthogonal axis in a cross-section of the rounded nanosheets to increase the width of the rounded nanowire channel structures to further increase drive strength and further reduce parasitic capacitance for further enhanced frequency performance.

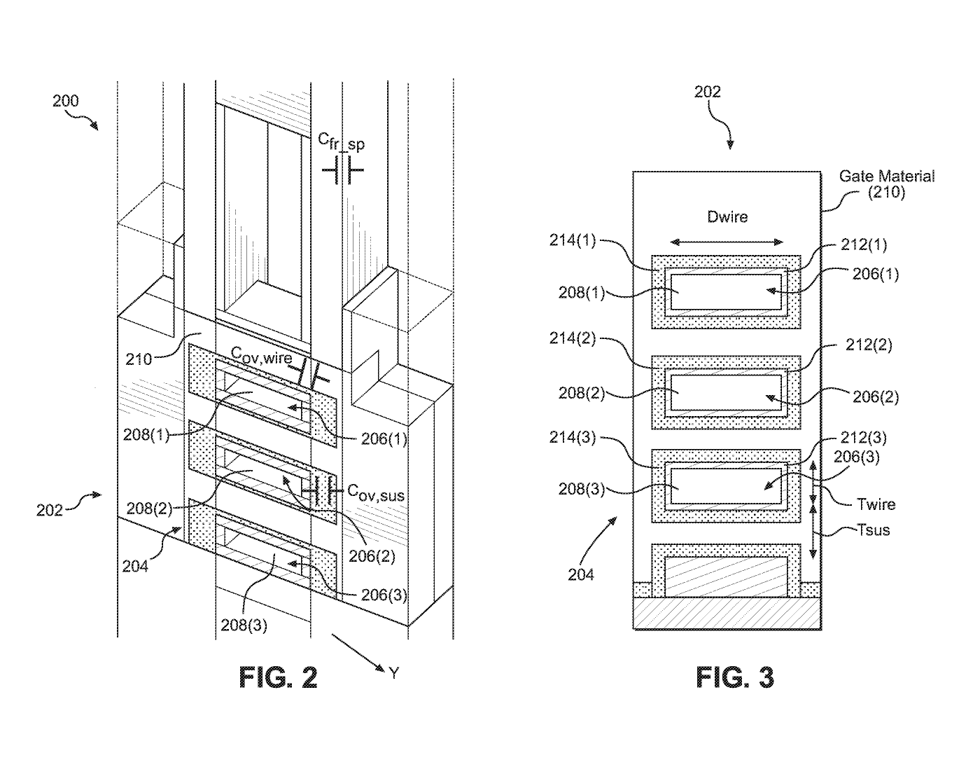

FIG. 2 illustrates an exemplary nanowire MOSFET 200 that does not include rounded nanowire structures for discussion purposes. As shown in FIG. 2, the nanowire MOSFET 200 includes a channel body 202 that includes a nanowire channel structure 204 that includes a plurality of nanowire structures 206(1)-206(3) that form a channel. In this example, the nanowire structures 206(1)-206(3) are nanoslabs 208(1)-208(3) that are elongated in the horizontal (X-axis) direction. FIG. 3 illustrates a close-up, side view of the channel body 202 in the nanowire MOSFET 200 in FIG. 2. As shown in FIGS. 2 and 3, a gate material 210 in the form of a metal material completely surrounds the nanowire structures 206(1)-206(3). Before the gate material 210 is disposed, an interfacial layer 212(1)-212(3) is disposed around the respective nanowire structures 206(1)-206(3) followed by a high-K dielectric material layer 214(1)-214(3) to insulate the gate material 210 from the nanowire structures 206(1)-206(3). In this manner, applying a voltage to the gate material 210 controls an electric field in the nanowire structures 206(1)-206(3) to cause current to flow through the nanowire structures 206(1)-206(3) during an active mode.

With reference to FIG. 3, the length of the nanowire structures 206(1)-206(3) is each of a height of Twire. The overall length of the nanowire structures 206(1)-206(3) determines the effective nanowire length in the channel body 202, and the drive strength of the nanowire MOSFET 200. Adjacent nanowire structures 206(1)-206(3) are separated a distance from each other labeled Tsus in FIG. 3. This distance Tsus is provided of a distance based on fabrication limitations to allow the gate material 210 to be disposed completely around and between the adjacent nanowire structures 206(1)-206(3) so that the gate material 210 can provide gate control of the channels formed by the nanowire structures 206(1)-206(3) to control the channel of the nanowire MOSFET 200. The distance Tsus may be fourteen (14) nanometers (nm) as an example in a conventional nanowire channel structure, such as the nanowire channel structure 204 in FIGS. 2 and 3. The distance Tsus may be controlled by fabrication limitations on the minimum space needed between adjacent nanowire structures 206(1)-206(3) to be able to insert the gate material 210 between adjacent nanowire structures 206(1)-206(3). It may be desired to minimize the distance Tsus between the adjacent nanowire structures 206(1)-206(3) to minimize the parasitic capacitance formed as a result of the adjacent nanowire structures 206(1)-206(3). Reducing parasitic capacitance can reduce the delay of the nanowire MOSFET 200 and/or increase its frequency performance, which may be important for example, if the nanowire MOSFET 200 is used in radio-frequency (RF) applications. Reducing the distance Tsus to reduce parasitic capacitance in the channel body 202 may also provide more area for including additional nanowire structures to provide increased drive strength of the nanowire MOSFET 200 for a given channel body 202 height size. However, again, fabrication limitations may prevent providing less distance Tsus between the adjacent nanowire structures 206(1)-206(3).

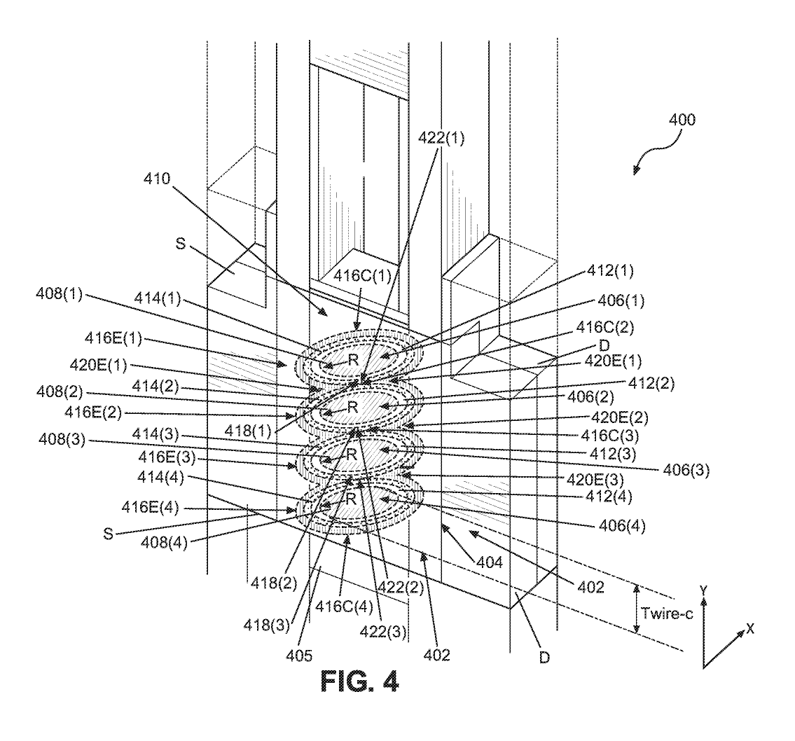

In this regard, FIG. 4 illustrates an exemplary nanowire MOSFET 400 that includes a channel body 402 having a nanowire channel structure 404 disposed on a substrate 405. The nanowire channel structure 404 employs rounded nanowire structures 406(1)-406(4), as opposed to the non-rounded nanowire structures 206(1)-206(3) in the nanowire MOSFET 200 in FIG. 2. The rounded nanowire structures 406(1)-406(4) are provided in the form of rounded nanoslabs 408(1)-408(4) in this example. As will be discussed in more detail below, providing the rounded nanowire structures 406(1)-406(4) in the nanowire MOSFET 400 allows the rounded nanowire structures 406(1)-406(4) to be fabricated closer together to further reduce parasitic capacitance to reduce delay of the nanowire MOSFET 400 and improve frequency performance. However, as discussed in more detail below, the rounded nanowire structures 406(1)-406(4) being rounded creates additional separation areas at rounded end portions to allow a gate material to be disposed around the rounded end portions for improved gate control.

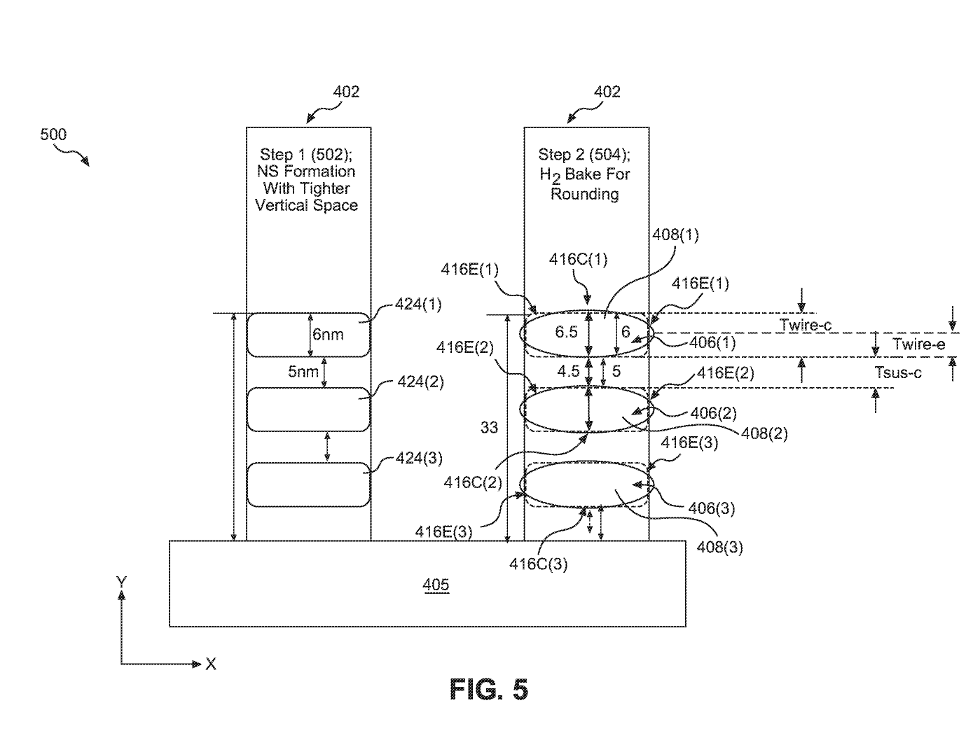

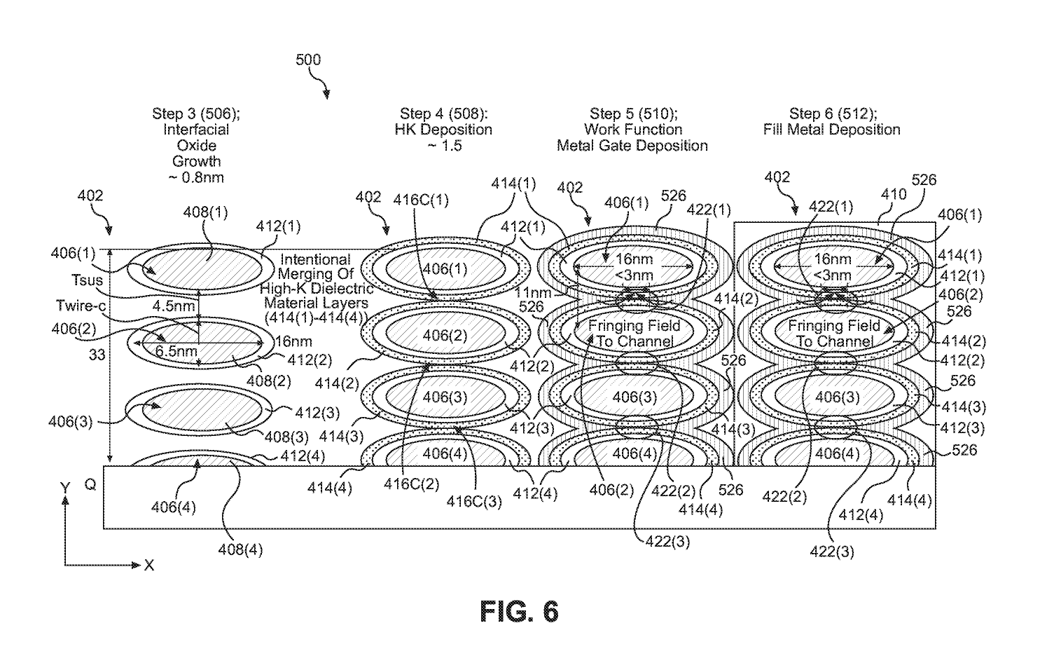

In this regard, with reference to FIG. 4, the nanowire MOSFET 400 includes the channel body 402 disposed between a drain (D) and a source (S). The channel body 402 includes the nanowire channel structure 404 that includes the plurality of rounded nanowire structures 406(1)-406(4) that form a channel between the drain (D) and the source (S). In this example, and as illustrated in more detail in FIGS. 5 and 6 discussed below, the rounded nanowire structures 406(1)-406(4) are the rounded nanoslabs 408(1)-408(4) that are elongated in the horizontal (X-axis) direction. The rounded nanoslabs 408(1)-408(4) may be formed from a Silicon (Si) material, as an example. A gate material 410 in the form of a metal material in this example surrounds the rounded nanowire structures 406(1)-406(4). Before the gate material 410 is disposed, interfacial layers 412(1)-412(4) are disposed around the respective rounded nanowire structures 406(1)-406(4) followed by a high-K dielectric material layer 414(1)-414(4) to insulate the gate material 410 from the rounded nanowire structures 406(1)-406(4). In this manner, applying a voltage to the gate material 410 controls an electric field in the rounded nanowire structures 406(1)-406(4) to cause current to flow through the rounded nanowire structures 406(1)-406(4) during an active mode. The overall length of the rounded nanowire structures 406(1)-406(4) determines the effective nanowire length in the channel body 402, and the drive strength of the nanowire MOSFET 400.

With continuing reference to FIG. 4, the rounded nanowire structures 406(1)-406(4) are arranged in a stacked fashion with the height in the Y-axis direction. Each of the rounded nanowire structures 406(1)-406(4) have rounded end portions 416E(1)-416E(4) and a center portion 416C(1)-416C(4) disposed between the respective rounded end portions 416E(1)-416E(4) that come to a point. With the rounded nanowire structures 406(1)-406(4) having the rounded end portions 416E(1)-416E(4) in this example, the center portions 416C(1)-416C(4) have a height Twire-c greater than a height Twire-e of the rounded end portions 416E(1)-416E(4), as shown in FIG. 5. In this example, the radius R of the rounded end portions 416E(1)-416E(4) is approximately 1.7 nm. As other non-limiting examples, the radius R of the rounded end portions 416E(1)-416E(4) may also be between 0.5 nm and 3.5 nm (e.g., 0.5 nm, 0.8 nm, 1.0 nm, 1.7 nm, 2.2 nm, 3.2 nm, 3.5 nm). The radius R of the rounded end portions 416E(1)-416E(4) may also be different between the rounded end portion 416E(1)-416E(4) for the same respective rounded nanowire structure 406(1)-406(4), and also between different rounded nanowire structures 406(1)-406(4). The radius R of the rounded end portions 416E(1)-416E(4) may also not be the same radius R for each rounded end portion 416E(1)-416E(4). A plurality of separation areas 418(1)-418(3) are disposed between the adjacent rounded nanowire structures 406(1)-406(4). In this example, the plurality of separation areas 418(1)-418(3) extend completely between respective adjacent rounded nanowire structures 406(1)-406(4), because the adjacent rounded nanowire structures 406(1)-406(4) are not fabricated to be in contact with each other.

With continuing reference to FIG. 4, and as will be discussed in more detail below with regard to FIGS. 5 and 6, during fabrication of the nanowire MOSFET 400, the gate material 410 is disposed around the rounded end portions 416E(1)-416E(4) of the rounded nanowire structures 406(1)-406(4). The gate material 410 extends into portions of the separation areas 418(1)-418(3). In this example, the gate material 410 does not completely surround each individual, rounded nanowire structure 406(1)-406(4). In this example, the center portions 416C(1)-416C(4) of the rounded nanowire structures 406(1)-406(4) are disposed the distance Tsus-c to each other such that when the interfacial layers 412(1)-412(4) and the high-K dielectric material layers 414(1)-414(4) are disposed around the rounded nanowire structures 406(1)-406(4), the high-k dielectric material layers 414(1)-414(4) surrounding the adjacent rounded nanowire structures 406(1)-406(4) merge together proximate the center portions 416C(1)-416C(4) in the separation areas 418(1)-418(3) between the adjacent rounded nanowire structures 406(1)-406(4). This allows the rounded nanowire structures 406(1)-406(4) to be placed more closely together to reduce parasitic capacitance of the channel body 402 while still achieving a desired gate control of the channel, because the gate material 410 is not required to extend completely in the separation areas 418(1)-418(3) between the adjacent rounded nanowire structures 406(1)-406(4). Fabrication limitations may limit the ability to dispose the gate material 410 within the entirety of the separation areas 418(1)-418(3) between the adjacent rounded nanowire structures 406(1)-406(4) around the center portions 416C(1)-416C(4), and to dispose the gate material 410 around the rounded nanowire structures 406(1)-406(4).

To provide gate control of the channel formed by the rounded nanowire structures 406(1)-406(4), the rounded nanowire structures 406(1)-406(4) are stacked with regard to each other in this example, such that the gate material 410 can surround the rounded end portions 416E(1)-416E(4) and extend into a portion of the separation areas 418(1)-418(3). The rounded end portions 416E(1)-416E(4) are also located farther away from adjacent rounded end portions 416E(1)-416E(4) to allow a larger space for the deposition of the gate material 410. In this manner, end portions 420E(1)-420E(3) of the gate material 410 come close enough to each other on sides of the center portions 416C(1)-416C(4) of the rounded nanowire structures 406(1)-406(4) (e.g., within 3 nm) to create a fringing field 422(1)-422(3) in the rounded nanowire structures 406(1)-406(4) in response to a voltage applied to the gate material 410. In this manner, the gate material 410 can still provide strong short channel control, but with the benefits of lower parasitic capacitance for reduced delay and improved frequency performance. Also, because the rounded nanowire structures 406(1)-406(4) can be located in the channel body 402 closer together, if desired, more nanowire structures can be provided for a given height of the channel body 402, or the channel body 402 can be reduced in height to provide the same equivalent channel length and control. For example, the overall height of the rounded nanowire structures 406(1)-406(4) may be 60 nm as compared to 126 nm for non-rounded nanowire structures provided in the channel body 402 to achieve an equivalent channel length (e.g., 5 nm) and gate control of the channel.

FIGS. 5 and 6 illustrate an exemplary process 500 of fabricating the channel body 402 of the nanowire MOSFET 400 in FIG. 4 that employs the rounded nanowire structures 406(1)-406(4). In this regard, a first exemplary step 502 shown in FIG. 5 involves formation of nanowire structures 424(1)-424(3) in the channel body 402 with less separation distance placed between adjacent nanowire structures 424(1)-424(3). For example, the distance between the adjacent nanowire structures 424(1)-424(3) is five (5) nm in this example. The center height of the nanowire structures 424(1)-424(3) is six (6) nm in this example. The length of the nanowire structures 424(1)-424(3) may be 16 nm as an example. Note that this also allows more nanowire structures 424(1)-424(3) to be disposed in the channel body 402 for a given channel body 402 height. Note that the nanowire structures 424(1)-424(3) are not initially rounded like the rounded nanowire structures 406(1)-406(4) in the final form of the nanowire MOSFET 400 in FIG. 4 in this example. A second exemplary step 504 in FIG. 5 involves baking or annealing the nanowire structures 424(1)-424(3) with Hydrogen (H₂) to round the nanowire structures 424(1)-424(3) to provide the rounded nanowire structures 406(1)-406(4). This creates the rounded end portions 416E(1)-416E(4) and the center portions 416C(1)-416C(4) disposed between the respective rounded end portions 416E(1)-416E(4) of the nanowire structures 406(1)-406(4). The annealing process still may provide the rounded nanowire structures 406(1)-406(4) to have the same length as the nanowire structures 424(1)-424(3) before being annealed for the rounding process, but the height is altered to create the rounded end portions 416E(1)-416E(4). The center portions 416C(1)-416C(4) have a height Twire-c (e.g., 6.5 nm) greater than the height Twire-e (e.g., <6 nm) of the rounded end portions 416E(1)-416E(4).

Note that while annealing may be a process that can be easily controlled, and thus desirable to use to create the rounded end portions 416E(1)-416E(4) of the rounded nanowire structures 406(1)-406(4), other methods of forming the rounded nanowire structures 406(1)-406(4) may be employed, including but not limited to etching, including chemical etching.

With reference to FIG. 6, the exemplary process 500 continues in a third exemplary step 506 where the interfacial layers 412(1)-412(4) are disposed around the rounded nanowire structures 406(1)-406(4). The interfacial layers 412(1)-412(4) may be provided based on an interfacial oxide growth at approximately 0.8 nm thick, as an example. In a next exemplary step 508, it may be desired to dispose the high-k dielectric material layers 414(1)-414(4) over the respective interfacial layers 412(1)-412(4) such that the high-k dielectric material layers 414(1)-414(4) are merged at the center portions 416C(1)-416C(4) of the rounded nanowire structures 406(1)-406(4). For example, if the distance between adjacent rounded nanowire structures 406(1)-406(4) is 4.5 nm, and the interfacial layers 412(1)-412(4) are 0.8 nm thick, this leaves 2.9 nm (4.5 nm−(0.8 nm*2)) of space for the high-k dielectric material layers 414(1)-414(4). Thus, if the high-k dielectric material layers 414(1)-414(4) are 1.5 nm thick (i.e., 1.5 nm*2=3.0 nm>2.9 nm), a merger of the high-k dielectric material layers 414(1)-414(4) between the adjacent nanowire structures 406(1)-406(4) will occur. In a next exemplary step 510, a work function gate material 526 is disposed around the high-k dielectric material layers 414(1)-414(4) of the rounded nanowire structures 406(1)-406(4) before a next step 512 of the gate material 410 being disposed around the work function gate material 526 to complete the channel body 402.

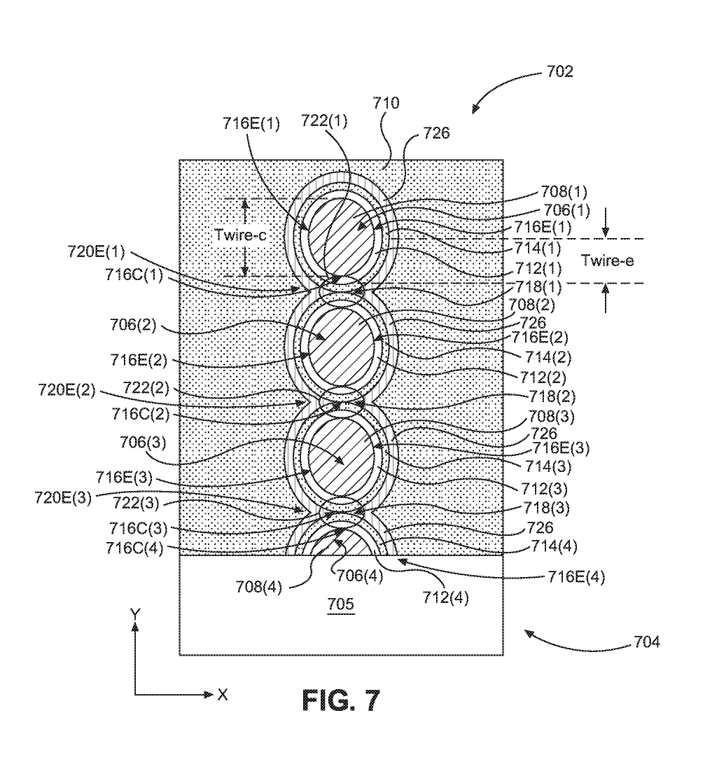

Other shapes of rounded nanowire structures are possible. For example, FIG. 7 is another exemplary channel body 702 that can be provided in a nanowire MOSFET. The channel body 702 is disposed on a substrate 705 and includes a nanowire channel structure 704 employing rounded nanowire structures 706(1)-706(4) elongated in a vertical dimension (i.e., along the Y-axis). The channel body 702 can be disposed between a drain (D) and a source (S) of a nanowire MOSFET. The channel body 702 includes the nanowire channel structure 704 that includes the rounded nanowire structures 706(1)-706(4) that form a channel between the drain (D) and the source (S). In this example, the rounded nanowire structures 706(1)-706(4) are rounded nanowires 708(1)-708(4). For example, the rounded nanowires 708(1)-708(4) may be formed from a Silicon (Si) material. A gate material 710 in the form of a metal material in this example surrounds the rounded nanowire structures 706(1)-706(4). Before the gate material 710 is disposed, a plurality of interfacial layers 712(1)-712(4) is disposed around the respective rounded nanowire structures 706(1)-706(4) followed by high-K dielectric material layers 714(1)-714(4) to insulate the gate material 710 from the rounded nanowire structures 706(1)-706(4). In this manner, applying a voltage to the gate material 710 controls an electric field in the rounded nanowire structures 706(1)-706(4) to cause current to flow through the rounded nanowire structures 706(1)-706(4) during an active mode. The overall length of the rounded nanowire structures 706(1)-706(4) determines the effective nanowire length in the channel body 702, and the drive strength of a nanowire MOSFET.

With continuing reference to FIG. 7, the rounded nanowire structures 706(1)-706(4) are arranged in a stacked arrangement. The fabrication of the rounded nanowire structures 706(1)-706(4) may be fabricated according to the process steps shown and discussed above with regard to the channel body 402 in FIG. 6. Each of the rounded nanowire structures 706(1)-706(4) have rounded end portions 716E(1)-716E(4) and a center portion 716C(1)-716C(4) disposed between the respective rounded end portions 716E(1)-716E(4) that come to a point. With the rounded nanowire structures 706(1)-706(4) having the rounded end portions 716E(1)-716E(4) in this example, the center portions 716C(1)-716C(4) have a height Twire-c greater than a height Twire-e of the rounded end portions 716E(1)-716E(4). A plurality of separation areas 718(1)-718(3) are disposed between the adjacent rounded nanowire structures 706(1)-706(4). In this example, the plurality of separation areas 718(1)-718(3) extend completely between respective adjacent rounded nanowire structures 706(1)-706(4), because the adjacent rounded nanowire structures 706(1)-706(4) are not fabricated to be in contact with each other. However, the gate material 710 may not extend completely in the separation areas 718(1)-718(3) due to process limitations.

To provide gate control of the channel formed by the rounded nanowire structures 706(1)-706(4), the rounded nanowire structures 706(1)-706(4) are stacked with regard to each other such that the gate material 710 can surround the rounded end portions 716E(1)-716E(4) and extend into a portion of the separation areas 718(1)-718(3). A work function gate material 726 is disposed around the high-k dielectric material layers 714(1)-714(4) of the rounded nanowire structures 706(1)-706(4) before the gate material 710 is disposed around the work function gate material 726 to complete the channel body 702. The rounded end portions 716E(1)-716E(4) are also located farther away from adjacent rounded end portions 716E(1)-716E(4) to allow a larger space for the deposition of the gate material 710. In this manner, end portions 720E(1)-720E(3) of the gate material 710 come close enough to each other on sides of the center portions 716C(1)-716C(4) of the rounded nanowire structures 706(1)-706(4) to create a fringing field 722(1)-722(3) in the rounded nanowire structures 706(1)-706(4) in response to a voltage applied to the gate material 710. In this manner, the gate material 710 can still provide strong short channel control, but with the benefits of lower parasitic capacitance for reduced delay and improved frequency performance. Also, because the rounded nanowire structures 706(1)-706(4) can be located in the channel body 702 closer together, if desired, more nanowire structures can be provided for a given height of the channel body 702, or the channel body 702 can be reduced in height to provide the same equivalent channel length and control.

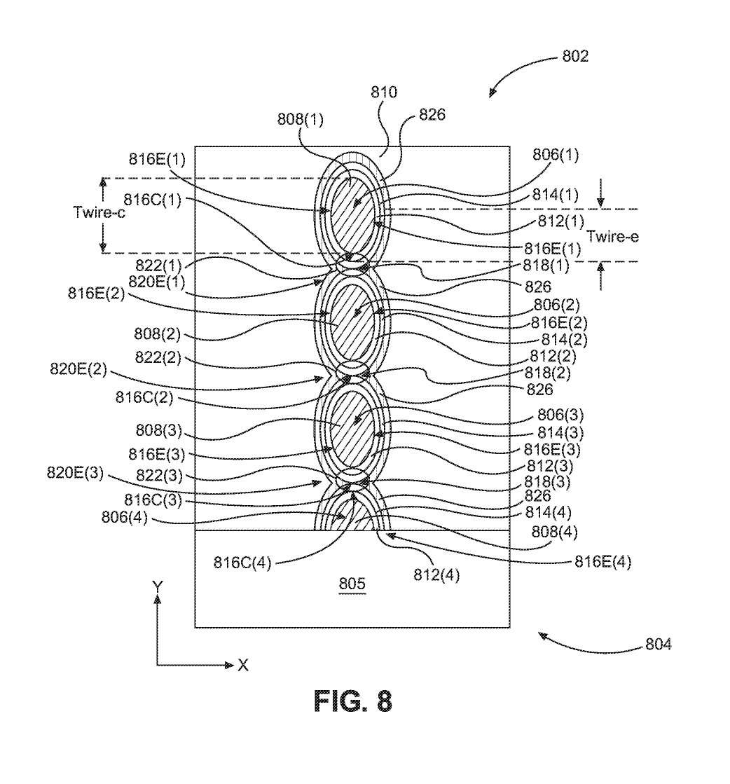

FIG. 8 is another exemplary channel body 802 that can be provided in a nanowire MOSFET. The channel body 802 is disposed on a substrate 805 and includes a nanowire channel structure 804 employing rounded nanowire structures 806(1)-806(4). The channel body 802 can be disposed between a drain (D) and a source (S) of a nanowire MOSFET. The channel body 802 includes the nanowire channel structure 804 that includes the rounded nanowire structures 806(1)-806(4) that form a channel between the drain (D) and the source (S). In this example, the rounded nanowire structures 806(1)-806(4) are rounded nanoslabs 808(1)-808(4) that are elongated in the vertical (i.e., Y-axis) direction. For example, the rounded nanoslabs 808(1)-808(4) may be formed from a Silicon (Si) material. A gate material 810 in the form of a metal material in this example surrounds the rounded nanowire structures 806(1)-806(4). Before the gate material 810 is disposed, a plurality of interfacial layers 812(1)-812(4) is disposed around the respective rounded nanowire structures 806(1)-806(4) followed by a high-K dielectric material layer 814(1)-814(4) to insulate the gate material 810 from the rounded nanowire structures 806(1)-806(4). A work function gate material 826 is disposed around the high-k dielectric material layers 814(1)-814(4) of the rounded nanowire structures 806(1)-806(4) before the gate material 810 is disposed around the work function gate material 826 to complete the channel body 802. In this manner, applying a voltage to the gate material 810 controls an electric field in the rounded nanowire structures 806(1)-806(4) to cause current to flow through the rounded nanowire structures 806(1)-806(4) during an active mode. The overall length of the rounded nanowire structures 806(1)-806(4) determines the effective nanowire length in the channel body 802, and the drive strength of a nanowire MOSFET.

With continuing reference to FIG. 8, the rounded nanowire structures 806(1)-806(4) are arranged in a stacked arrangement. The fabrication of the rounded nanowire structures 806(1)-806(4) may be fabricated according to the process steps shown and discussed above with regard to the channel body 402 in FIG. 6. Each of the rounded nanowire structures 806(1)-806(4) have rounded end portions 816E(1)-816E(4) and a center portion 816C(1)-816C(4) disposed between the respective rounded end portions 816E(1)-816E(4) that come to a point. With the rounded nanowire structures 806(1)-806(4) having the rounded end portions 816E(1)-816E(4) in this example, the center portions 816C(1)-816C(4) have a height Twire-c greater than a height Twire-e of the rounded end portions 816E(1)-816E(4). A plurality of separation areas 818(1)-818(3) are disposed between the adjacent rounded nanowire structures 806(1)-806(4). In this example, the plurality of separation areas 818(1)-818(3) extend completely between respective adjacent rounded nanowire structures 806(1)-806(4), because the adjacent rounded nanowire structures 806(1)-806(4) are not fabricated to be in contact with each other. However, the gate material 810 may not extend completely in the separation areas 818(1)-818(3) due to process limitations.

To provide gate control of the channel formed by the rounded nanowire structures 806(1)-806(4), the rounded nanowire structures 806(1)-806(4) are stacked with regard to each other such that the gate material 810 can surround the rounded end portions 816E(1)-816E(4) and extend into a portion of the separation areas 818(1)-818(3). The rounded end portions 816E(1)-816E(4) are also located farther away from the adjacent rounded end portions 816E(1)-816E(4) to allow a larger space for the deposition of the gate material 810. In this manner, end portions 820E(1)-820E(3) of the gate material 810 come close enough to each other on sides of the center portions 816C(1)-816C(4) of the rounded nanowire structures 806(1)-806(4) to create a fringing field 822(1)-822(3) in the rounded nanowire structures 806(1)-806(4) in response to a voltage applied to the gate material 810. In this manner, the gate material 810 can still provide strong short channel control, but with the benefits of lower parasitic capacitance for reduced delay and improved frequency performance. Also, because the rounded nanowire structures 806(1)-806(4) can be located in the channel body 802 closer together, if desired, more nanowire structures can be provided for a given height of the channel body 802, or the channel body 802 can be reduced in height to provide the same equivalent channel length and control.

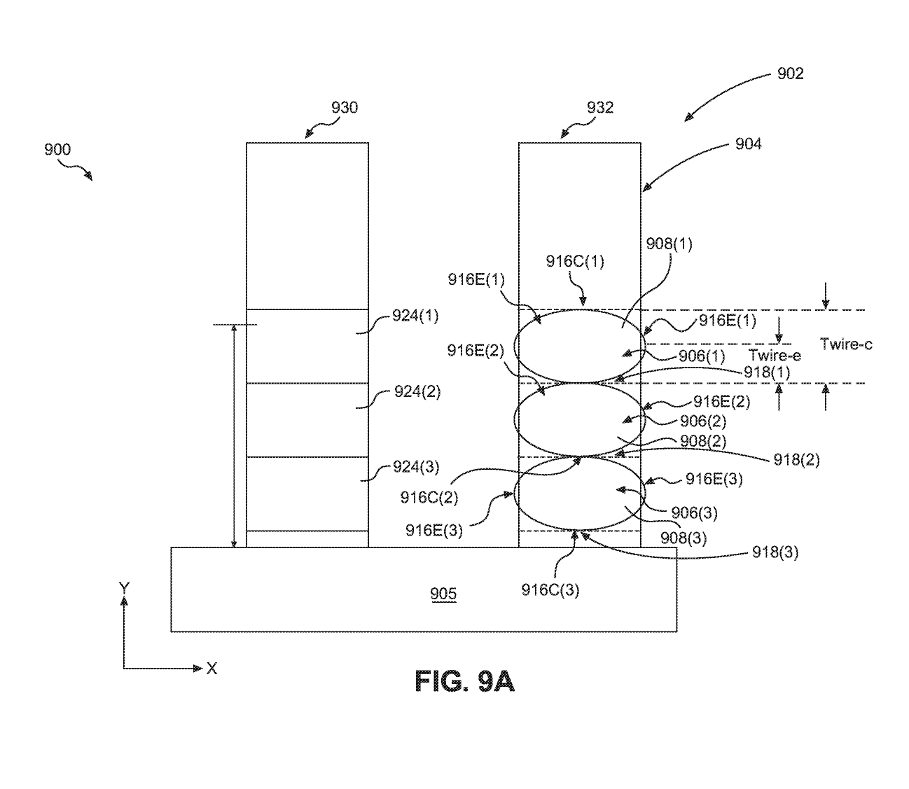

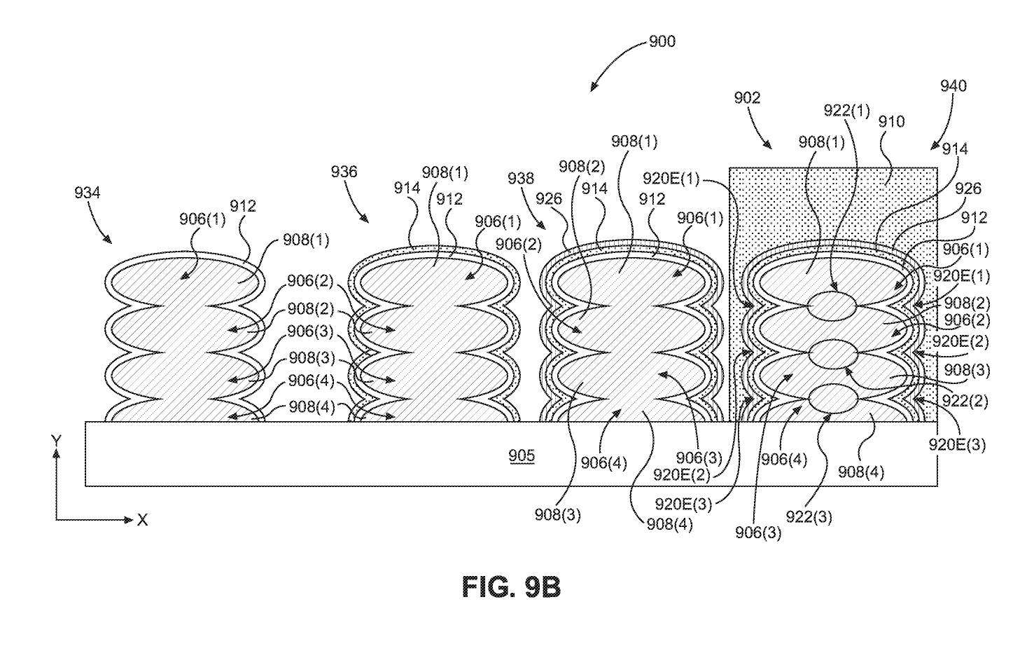

FIGS. 9A and 9B illustrate another exemplary channel body 902 that can be provided in a nanowire MOSFET. The channel body 902 is disposed on a substrate 905 and includes a nanowire channel structure 904 employing rounded nanowire structures 906(1)-906(4). The channel body 902 can be disposed between a drain (D) and a source (S) of a nanowire MOSFET. As discussed in more detail below, the rounded nanowire structures 906(1)-906(4) are formed to be in contact with each other. The channel body 902 includes the nanowire channel structure 904 that includes the rounded nanowire structures 906(1)-906(4) that form a channel between the drain (D) and the source (S). In this example, the rounded nanowire structures 906(1)-906(4) are rounded nanoslabs 908(1)-908(4) that are elongated in the horizontal (X-axis) direction similar to the rounded nanoslabs 408(1)-408(4) in FIG. 6. For example, the rounded nanoslabs 908(1)-908(4) may be formed from a Silicon (Si) material. A gate material 910 in the form of a metal material in this example surrounds the rounded nanowire structures 906(1)-906(4). Before the gate material 910 is disposed, a single interfacial layer 912 is disposed around the respective rounded nanowire structure 906(1) followed by a single high-K dielectric material layer 914 to insulate the gate material 910 from the rounded nanowire structure 906(1). In this manner, applying a voltage to the gate material 910 controls an electric field in the rounded nanowire structures 906(1)-906(4) to cause current to flow through the rounded nanowire structures 906(1)-906(4) during an active mode. The overall length of the rounded nanowire structures 906(1)-906(4) determines the effective nanowire length in the channel body 902, and the drive strength of a nanowire MOSFET.

With continuing reference to FIGS. 9A and 9B, the rounded nanowire structures 906(1)-906(4) are arranged in a stacked arrangement. The fabrication of the rounded nanowire structures 906(1)-906(4) may be fabricated according to the process steps shown and discussed above with regard to the channel body 402 in FIG. 6. Each of the rounded nanowire structures 906(1)-906(4) have the rounded end portions 916E(1)-916E(4) and the center portion 916C(1)-916C(4) disposed between the respective rounded end portions 916E(1)-916E(4) that come to a point. With the rounded nanowire structures 906(1)-906(4) having the rounded end portions 916E(1)-916E(4) in this example, the center portions 916C(1)-916C(4) have a height Twire-c greater than a height Twire-e of the rounded end portions 916E(1)-916E(4). A plurality of separation areas 918(1)-918(3) are disposed between the adjacent rounded nanowire structures 906(1)-906(4). In this example, the plurality of separation areas 918(1)-918(3) do not extend completely between the respective adjacent rounded nanowire structures 906(1)-906(4), because the adjacent rounded nanowire structures 906(1)-906(4) are fabricated to be in contact with each other as shown in FIGS. 9A and 9B. However, the gate material 910 may not extend completely in the separation areas 918(1)-918(3) due to process limitations.

To provide gate control of the channel formed by the rounded nanowire structures 906(1)-906(4), the rounded nanowire structures 906(1)-906(4) are stacked with regard to each other such that the gate material 910 can surround the rounded end portions 916E(1)-916E(4) and extend into a portion of the separation areas 918(1)-918(3). The rounded end portions 916E(1)-916E(4) are also located farther away from adjacent rounded end portions 916E(1)-916E(4) to allow a larger space for the deposition of the gate material 910. In this manner, as shown in FIG. 9B, end portions 920E(1)-920E(3) of the gate material 910 come close enough to each other on sides of the center portions 916C(1)-916C(4) of the rounded nanowire structures 906(1)-906(4) to create a fringing field 922(1)-922(3) in the rounded nanowire structures 906(1)-906(4) in response to a voltage applied to the gate material 910. In this manner, the gate material 910 can still provide strong short channel control, but with the benefit of lower parasitic capacitance for reduced delay and improved frequency performance. Also, because the rounded nanowire structures 906(1)-906(4) can be located in the channel body 902 closer together, more nanowire structures can be provided for a given height of the channel body 902 if desired, and/or the channel body 902 can be reduced in height to provide the same equivalent channel length and control.

FIGS. 9A and 9B also illustrate an exemplary process 900 of fabricating the channel body 902 that employs the rounded nanowire structures 906(1)-906(4). In this regard, a first exemplary step 930 shown in FIG. 9A involves formation of nanowire structures 924(1)-924(4) in the channel body 902 with less distance placed between adjacent nanowire structures 924(1)-924(4). Note that this also allows more nanowire structures 924(1)-924(4) to be disposed in the channel body 902 for a given channel body 902 height. Note that the nanowire structures 924(1)-924(4) are not initially rounded. A second exemplary step 932 shown in FIG. 9A involves baking or annealing the nanowire structures 924(1)-924(4) with Hydrogen (H₂) to round the nanowire structures 924(1)-924(4) to provide the rounded nanowire structures 906(1)-906(4). This creates the rounded end portions 916E(1)-916E(4) and the center portions 916C(1)-916C(4) disposed between the respective rounded end portions 916E(1)-916E(4) of the nanowire structures 924(1)-924(4). The nanowire structures 924(1)-924(4) are fabricated to be in contact with each other at the center portions 916C(1)-916C(4). The annealing process still may provide the rounded nanowire structures 906(1)-906(4) with the same length as the nanowire structures 924(1)-924(4) before being annealed for the rounding process, but the height is altered to create the rounded end portions 916E(1)-916E(4). The center portions 916C(1)-916C(4) have a height Twire-c (e.g., 6.5 nm) greater than the height Twire-e (e.g., <6 nm) of the rounded end portions 916E(1)-916E(4), as shown in FIG. 9A.

Note that while annealing may be a process that can be easily controlled, and thus desirable to use to create the rounded end portions 916E(1)-916E(4) of the rounded nanowire structures 906(1)-906(4), other methods of forming the rounded nanowire structures 906(1)-906(4) may be employed, including but not limited to etching, including chemical etching.

With reference to FIG. 9B, the exemplary process 900 continues in a third exemplary step 934 where a single interfacial layer 912 is disposed around the rounded nanowire structure 906(1). The interfacial layer 912 may be provided based on an interfacial oxide growth at approximately 0.8 nm thick, as an example. In a next exemplary step 936 in FIG. 9B, it may be desired to dispose a high-k dielectric material layer 914 over the interfacial layer 912. In a next exemplary step 938 in FIG. 9B, a work function gate material 926 is disposed around the high-k dielectric material layer 914 of the rounded nanowire structure 906(1) before a next step 940 of the gate material 910 is disposed around the work function gate material 926 to complete the channel body 902.

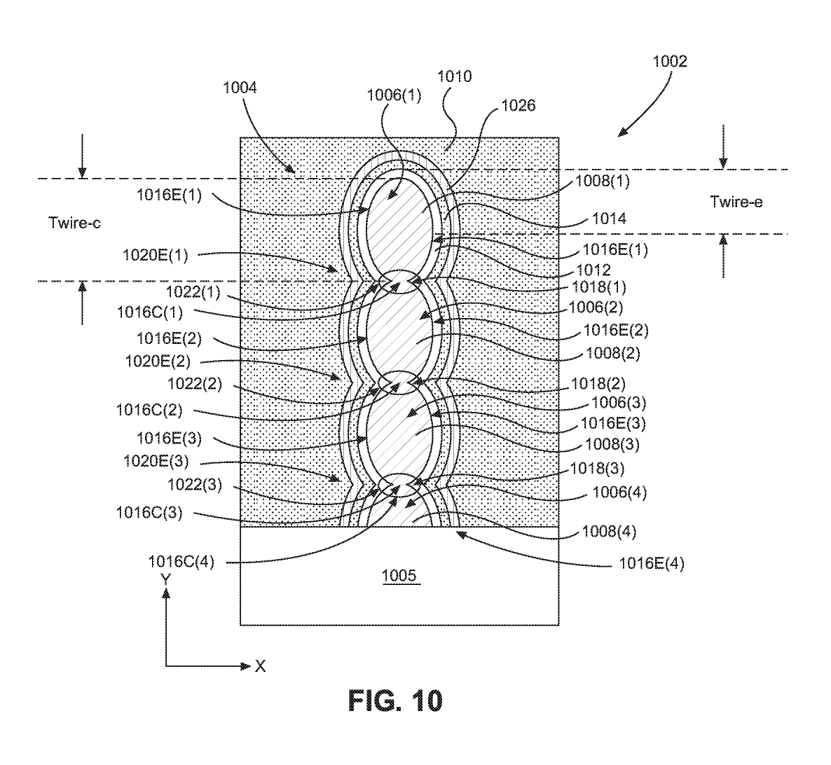

FIG. 10 is another exemplary channel body 1002 that can be provided in a nanowire MOSFET. The channel body 1002 is disposed on a substrate 1005 and includes a nanowire channel structure 1004 employing rounded nanowire structures 1006(1)-1006(4). The channel body 1002 can be disposed between a drain (D) and a source (S) of a nanowire MOSFET. As discussed in more detail below, the rounded nanowire structures 1006(1)-1006(4) are formed to be in contact with each other. The channel body 1002 includes the nanowire channel structure 1004 that includes the rounded nanowire structures 1006(1)-1006(4) that form a channel between the drain (D) and the source (S). In this example, the rounded nanowire structures 1006(1)-1006(4) are rounded nanoslabs 1008(1)-1008(4) that are elongated in the vertical (Y-axis) direction. For example, the rounded nanoslabs 1008(1)-1008(4) may be formed from a Silicon (Si) material. A gate material 1010 in the form of a metal material in this example surrounds the rounded nanowire structures 1006(1)-1006(4). Before the gate material 1010 is disposed, a single interfacial layer 1012 is disposed around the respective rounded nanowire structure 1006(1) followed by a high-K dielectric material layer 1014 to insulate the gate material 1010 from the rounded nanowire structure 1006(1). A work function gate material 1026 is disposed around the high-k dielectric material layer 1014 of the rounded nanowire structure 1006(1) before the gate material 1010 is disposed around the work function gate material 1026 to complete the channel body 1002. In this manner, applying a voltage to the gate material 1010 controls an electric field in the rounded nanowire structures 1006(1)-1006(4) to cause current to flow through the rounded nanowire structures 1006(1)-1006(4) during an active mode. The overall length of the rounded nanowire structures 1006(1)-1006(4) determines the effective nanowire length in the channel body 1002, and the drive strength of a nanowire MOSFET.

With continuing reference to FIG. 10, the rounded nanowire structures 1006(1)-1006(4) are arranged in a stacked arrangement. The fabrication of the rounded nanowire structures 1006(1)-1006(4) may be fabricated according to the process steps shown and discussed above with regard to the channel body 402 in FIG. 6. Each of the rounded nanowire structures 1006(1)-1006(4) have rounded end portions 1016E(1)-1016E(4) and a center portion 1016C(1)-1016C(4) disposed between the respective rounded end portions 1016E(1)-1016E(4) that come to a point. With the rounded nanowire structures 1006(1)-1006(4) having the rounded end portions 1016E(1)-1016E(4) in this example, the center portions 1016C(1)-1016C(4) have a height Twire-c greater than a height Twire-e of the rounded end portions 1016E(1)-1016E(4). A plurality of separation areas 1018(1)-1018(3) are disposed between the adjacent rounded nanowire structures 1006(1)-1006(4). In this example, the plurality of separation areas 1018(1)-1018(3) do not extend completely between respective adjacent rounded nanowire structures 1006(1)-1006(4), because the adjacent rounded nanowire structures 1006(1)-1006(4) are fabricated to be in contact with each other as shown in FIG. 10.

To provide gate control of the channel formed by the rounded nanowire structures 1006(1)-1006(4), the rounded nanowire structures 1006(1)-1006(4) are stacked with regard to each other such that the gate material 1010 can surround the rounded end portions 1016E(1)-1016E(4) and extend into a portion of the separation areas 1018(1)-1018(3). The rounded end portions 1016E(1)-1016E(4) are also located farther away from adjacent rounded end portions 1016E(1)-1016E(4) to allow a larger space for the deposition of the gate material 1010. In this manner, end portions 1020E(1)-1020E(3) of the gate material 1010 come close enough to each other on sides of the center portions 1016C(1)-1016C(4) of the rounded nanowire structures 1006(1)-1006(4) to create a fringing field 1022(1)-1022(3) in the rounded nanowire structures 1006(1)-1006(4) in response to a voltage applied to the gate material 1010. In this manner, the gate material 1010 can still provide strong short channel control, but with the benefits of lower parasitic capacitance for reduced delay and improved frequency performance. Also, because the rounded nanowire structures 1006(1)-1006(4) can be located in the channel body 1002 closer together, if desired, more nanowire structures can be provided for a given height of the channel body 1002, or the channel body 1002 can be reduced in height to provide the same equivalent channel length and control.

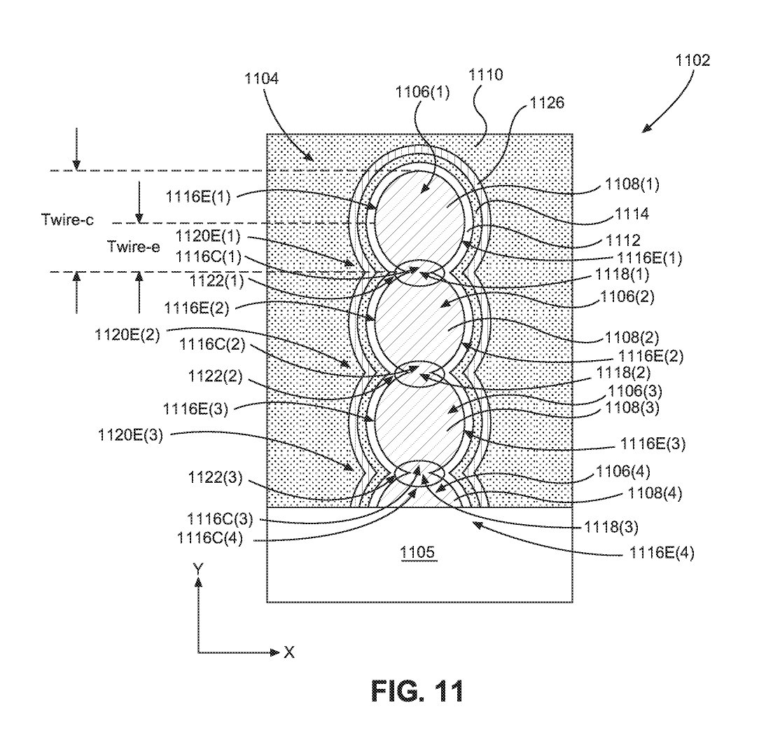

FIG. 11 is another exemplary channel body 1102 that can be provided in a nanowire MOSFET. The channel body 1102 is disposed on a substrate 1105 and includes a nanowire channel structure 1104 employing rounded nanowire structures 1106(1)-1106(4). The channel body 1102 can be disposed between a drain (D) and a source (S) of a nanowire MOSFET. As discussed in more detail below, the rounded nanowire structures 1106(1)-1106(4) are formed to be in contact with each other. The channel body 1102 includes the nanowire channel structure 1104 that includes the rounded nanowire structures 1106(1)-1106(4) that form a channel between the drain (D) and the source (S). In this example, the rounded nanowire structures 1106(1)-1106(4) are rounded nanowires 1108(1)-1108(4). For example, the rounded nanowires 1108(1)-1108(4) may be formed from a Silicon (Si) material. A gate material 1110 in the form of a metal material in this example surrounds the rounded nanowire structures 1106(1)-1106(4). Before the gate material 1110 is disposed, a single interfacial layer 1112 is disposed around the respective rounded nanowire structure 1106(1) followed by a high-K dielectric material layer 1114 to insulate the gate material 1110 from the rounded nanowire structure 1106(1). A work function gate material 1126 is disposed around the high-k dielectric material layer 1114 of the rounded nanowire structure 1106(1) before the gate material 1110 is disposed around the work function gate material 1126 to complete the channel body 1102. In this manner, applying a voltage to the gate material 1110 controls an electric field in the rounded nanowire structures 1106(1)-1106(4) to cause current to flow through the rounded nanowire structures 1106(1)-1106(4) during an active mode. The overall length of the rounded nanowire structures 1106(1)-1106(4) determines the effective nanowire length in the channel body 1102, and the drive strength of a nanowire MOSFET.

With continuing reference to FIG. 11, the rounded nanowire structures 1106(1)-1106(4) are arranged in a stacked arrangement. The fabrication of the rounded nanowire structures 1106(1)-1106(4) may be fabricated according to the process steps shown and discussed above with regard to the channel body 402 in FIG. 6. Each of the rounded nanowire structures 1106(1)-1106(4) have rounded end portions 1116E(1)-1116E(4) and a center portion 1116C(1)-1116C(4) disposed between the respective rounded end portions 1116E(1)-1116E(4) that come to a point. With the rounded nanowire structures 1106(1)-1106(4) having the rounded end portions 1116E(1)-1116E(4) in this example, the center portions 1116C(1)-1116C(4) have a height Twire-c greater than a height Twire-e of the rounded end portions 1116E(1)-1116E(4). A plurality of separation areas 1118(1)-1118(3) are disposed between the adjacent rounded nanowire structures 1106(1)-1106(4). In this example, the plurality of separation areas 1118(1)-1118(3) do not extend completely between respective adjacent rounded nanowire structures 1106(1)-1106(4), because the adjacent rounded nanowire structures 1106(1)-1106(4) are fabricated to be in contact with each other as shown in FIG. 11.

To provide gate control of the channel formed by the rounded nanowire structures 1106(1)-1106(4), the rounded nanowire structures 1106(1)-1106(4) are stacked with regard to each other such that the gate material 1110 can surround the rounded end portions 1116E(1)-1116E(4) and extend into a portion of the separation areas 1118(1)-1118(3). The rounded end portions 1116E(1)-1116E(4) are also located farther away from adjacent rounded end portions 1116E(1)-1116E(4) to allow a larger space for the deposition of the gate material 1110. In this manner, end portions 1120E(1)-1120E(3) of the gate material 1110 come close enough to each other on sides of the center portions 1116C(1)-1116C(4) of the rounded nanowire structures 1106(1)-1106(4) to create a fringing field 1122(1)-1122(3) in the rounded nanowire structures 1106(1)-1106(4) in response to a voltage applied to the gate material 1110. In this manner, the gate material 1110 can still provide strong short channel control, but with the benefits of lower parasitic capacitance for reduced delay and improved frequency performance. Also, because the rounded nanowire structures 1106(1)-1106(4) can be located in the channel body 1102 closer together, if desired, more nanowire structures can be provided for a given height of the channel body 1102, or the channel body 1102 can be reduced in height to provide the same equivalent channel length and control.

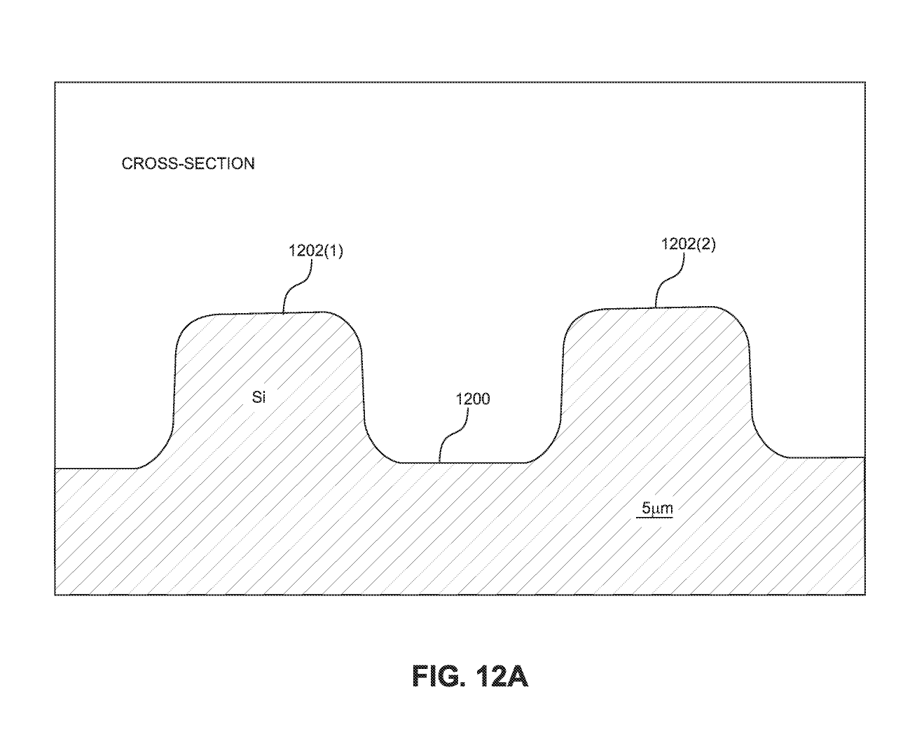

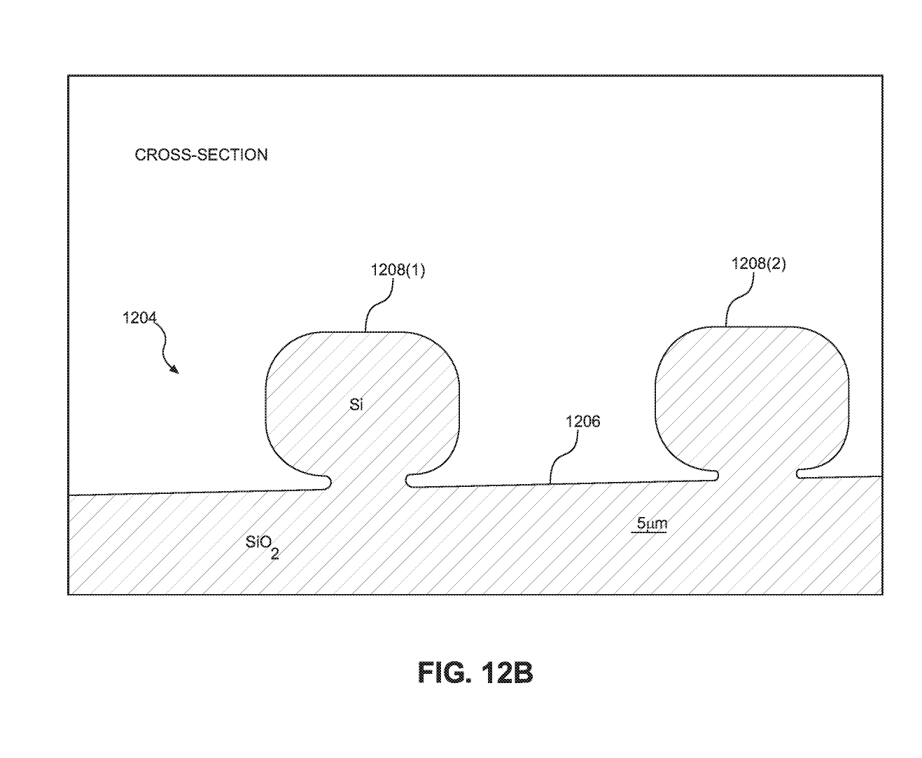

As discussed above, use of hydrogen to anneal any of the nanowire structures described above can be employed to round off the rounded end portions 416E(1)-416E(4) of the nanowire structures 424(1)-424(3) to provide the rounded nanowire structures 406(1)-406(4). In this regard, to show the effectiveness of hydrogen annealing, FIG. 12A illustrates a cross-section of an exemplary bulk Silicon (Si) body 1200 with etched comb structures 1202(1), 1202(2) rounded after the application of hydrogen annealing. FIG. 12B illustrates a cross-section of an exemplary silicon-on-insulator (SOI) 1204 that includes a Silicon Oxide (SiO₂) body 1206 with Silicon comb structures 1208(1), 1208(2) rounded after the application of hydrogen annealing.

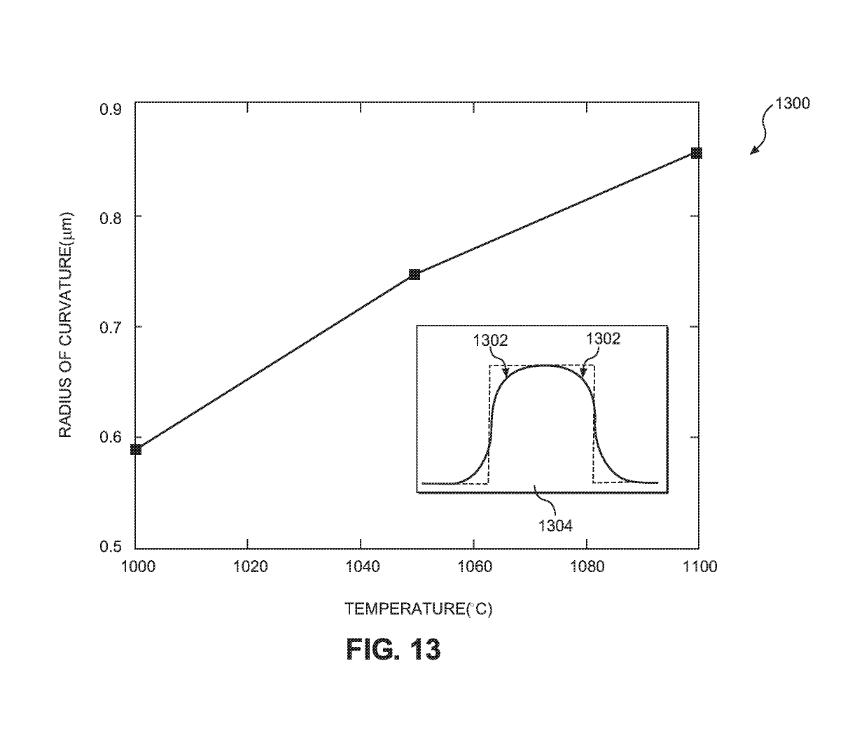

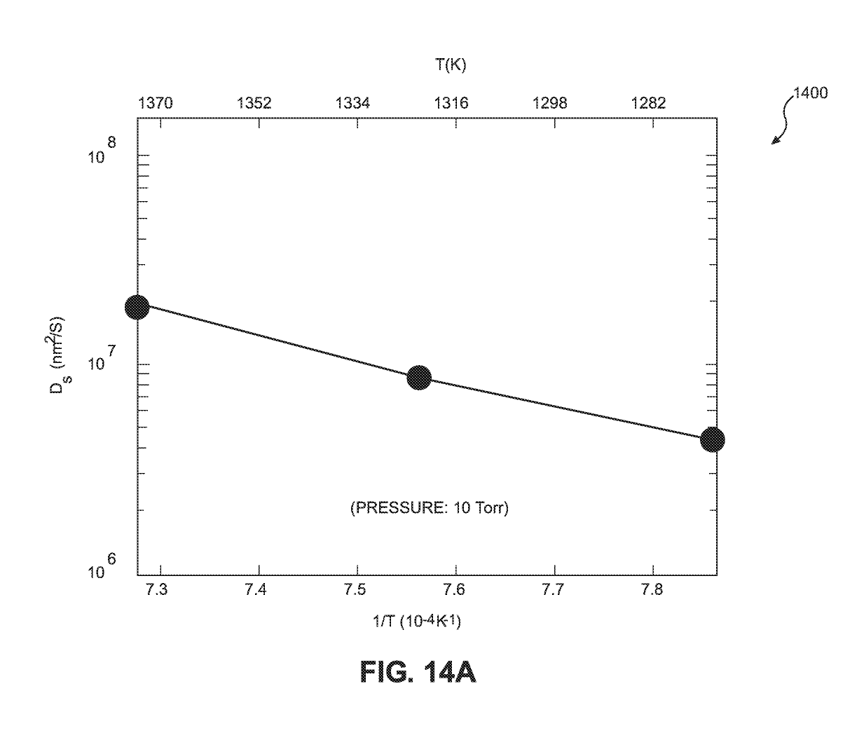

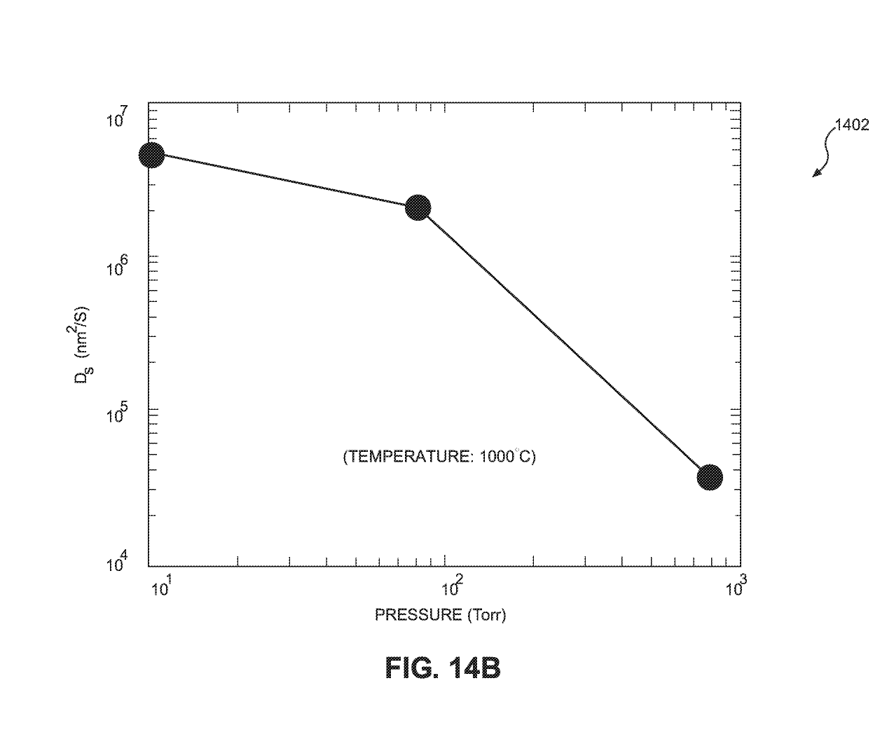

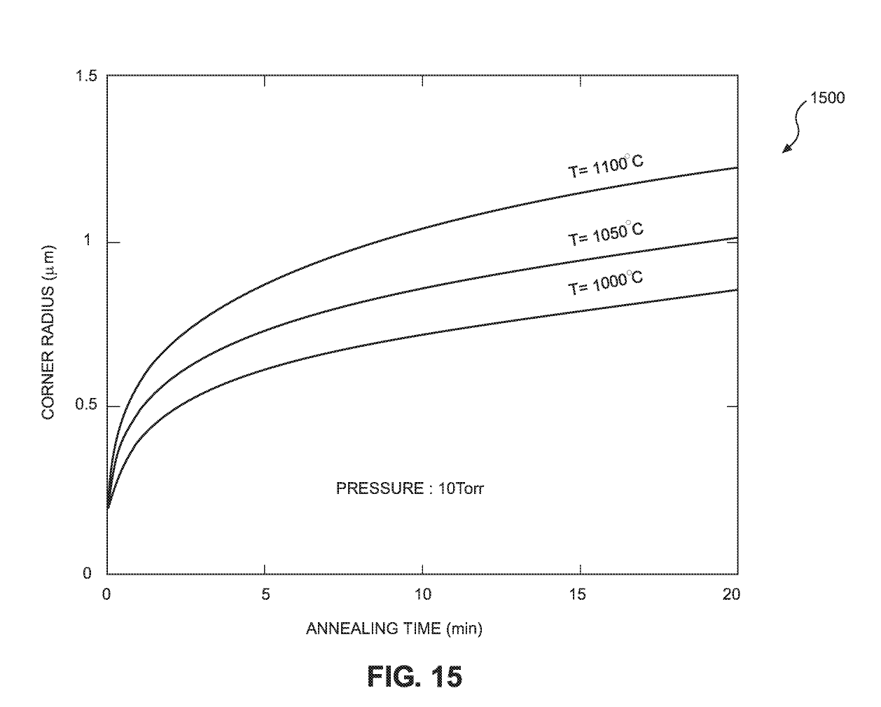

FIG. 13 is a graph 1300 illustrating an exemplary radius of curvature formed on corners 1302 of a Si structure 1304 from hydrogen annealing as a function of temperature. FIGS. 14A and 14B are graphs 1400, 1402 illustrating an exemplary surface diffusion coefficient of a hydrogen annealed Si structure as a function of temperature and pressure, respectively. FIG. 15 is a graph 1500 illustrating exemplary corner radiuses of a hydrogen annealed Si structure as a function of temperature and annealing time.

Nanowire MOSFETs employing a nanowire channel structure having rounded nanowire structures may be provided in or integrated into any processor-based device.

Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

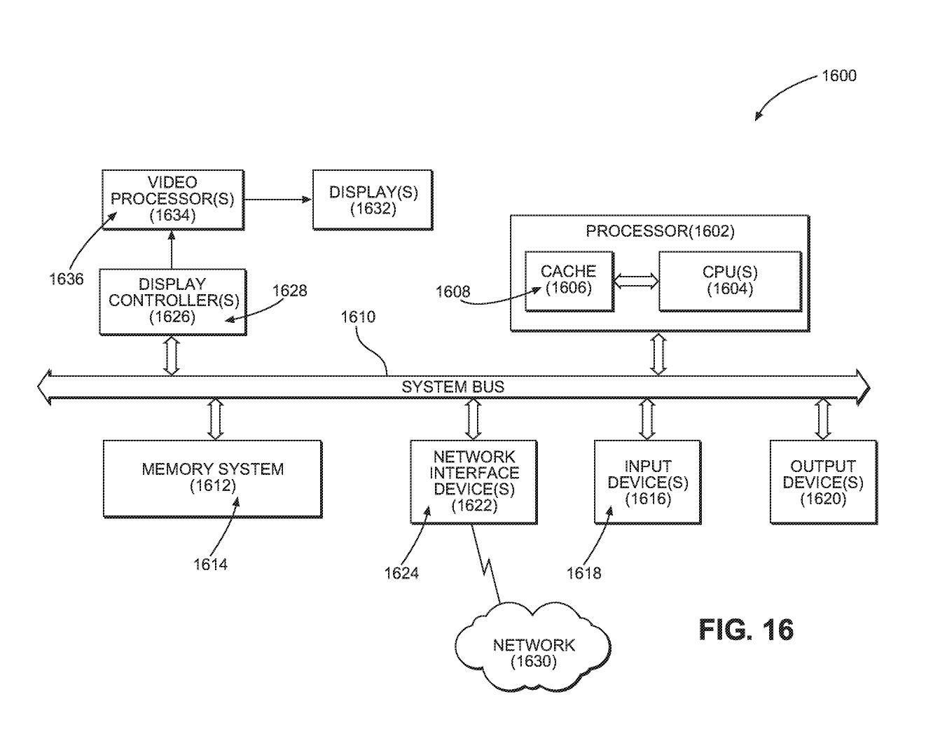

In this regard, FIG. 16 illustrates an example of a processor-based system 1600 that can include nanowire MOSFETs employing nanowire channel structures that include rounded nanowire structures. In this example, the processor-based system 1600 includes a processor 1602 that includes one or more CPUs 1604. The processor 1602 may have cache memory 1606 coupled to the CPU(s) 1604 for rapid access to temporarily stored data. The cache memory 1606 may include nanowire MOSFETs 1608 employing nanowire channel structures that include rounded nanowire structures. The processor 1602 is coupled to a system bus 1610 and can intercouple master and slave devices included in the processor-based system 1600. As is well known, the processor 1602 communicates with these other devices by exchanging address, control, and data information over the system bus 1610. Although not illustrated in FIG. 16, multiple system buses 1610 could be provided, wherein each system bus 1610 constitutes a different fabric. For example, the processor 1602 can communicate bus transaction requests to a memory system 1612 as an example of a slave device. The memory system 1612 may include memory structures or arrays that include nanowire MOSFETs 1614 employing nanowire channel structures that include rounded nanowire structures, as an example.

Other master and slave devices can be connected to the system bus 1600. As illustrated in FIG. 16, these devices can include the memory system 1612, one or more input devices 1616, which can include nanowire MOSFETs 1618 employing nanowire channel structures that include rounded nanowire structures as an example, one or more output devices 1620, one or more network interface devices 1622, which can include nanowire MOSFETs 1624 employing nanowire channel structures that include rounded nanowire structures as an example, and one or more display controllers 1626, including nanowire MOSFETs 1628 employing nanowire channel structures that include rounded nanowire structures, as examples. The input device(s) 1616 can include any type of input device, including but not limited to input keys, switches, voice processors, etc. The output device(s) 1620 can include any type of output device, including but not limited to audio, video, other visual indicators, etc. The network interface device(s) 1622 can be any devices configured to allow exchange of data to and from a network 1630. The network 1630 can be any type of network, including but not limited to a wired or wireless network, a private or public network, a local area network (LAN), a wireless local area network (WLAN), a wide area network (WAN), a BLUETOOTH™ network, and the Internet. The network interface device(s) 1622 can be configured to support any type of communications protocol desired.

The processor 1602 may also be configured to access the display controller(s) 1626 over the system bus 1610 to control information sent to one or more displays 1632. The display controller(s) 1626 sends information to the display(s) 1632 to be displayed via one or more video processors 1634, which process the information to be displayed into a format suitable for the display(s) 1632. The video processor(s) 1634 can include nanowire MOSFETs 1636 employing nanowire channel structures that include rounded nanowire structures, as an example. The display(s) 1632 can include any type of display, including but not limited to a cathode ray tube (CRT), a liquid crystal display (LCD), a plasma display, etc.

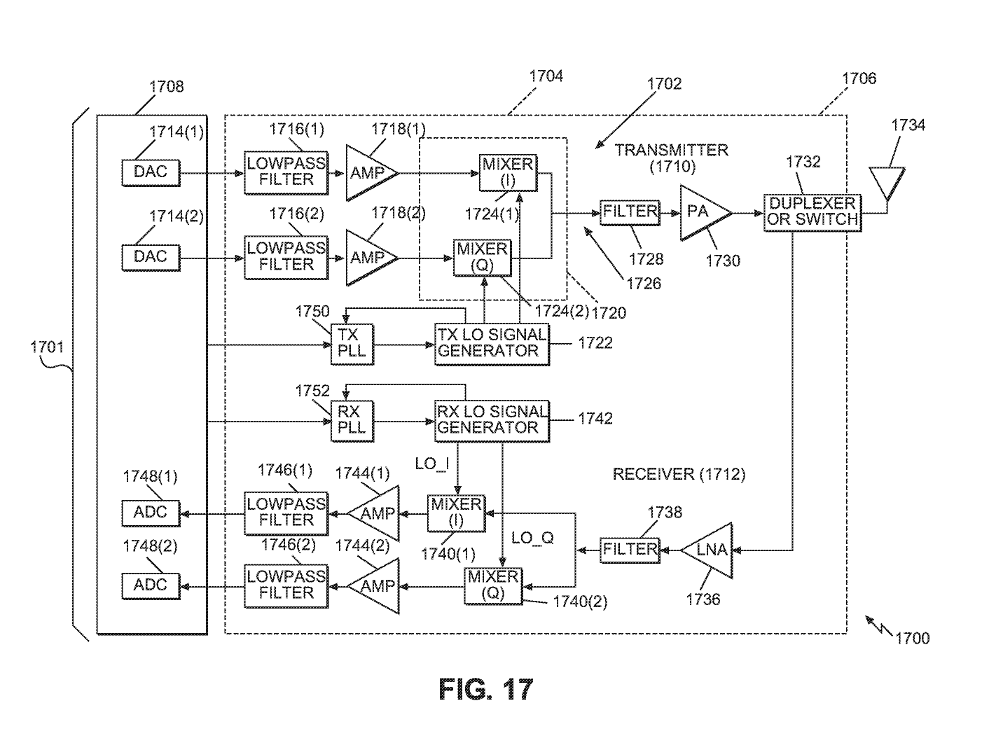

FIG. 17 illustrates an example of a wireless communications device 1700 that can include nanowire MOSFETs 1701 having a nanowire channel structure employing rounded nanowires, including but not limited to the rounded nanowire structures illustrated in FIGS. 4-11. In this regard, the wireless communications device 1700 may be provided in an integrated circuit (IC) 1702. The wireless communications device 1700 may include or be provided in any of the above referenced devices, as examples. As shown in FIG. 17, the wireless communications device 1700 includes a transceiver 1704 and a data processor 1708. The transceiver 1704 and/or the data processor 1708 may include nanowire MOSFETs 1701 having a nanowire channel structure employing rounded nanowires, including but not limited to the rounded nanowire structures illustrated in FIGS. 4-11. The data processor 1708 may include a memory (not shown) to store data and program codes. The transceiver 1704 includes a transmitter 1710 and a receiver 1712 that support bi-directional communication. In general, the wireless communications device 1700 may include any number of transmitters and/or receivers for any number of communication systems and frequency bands. All or a portion of the transceiver 1704 may be implemented on one or more analog ICs, RF ICs (RFICs), mixed-signal ICs, etc.

A transmitter or a receiver may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the wireless communications device 1700 in FIG. 17, the transmitter 1710 and the receiver 1712 are implemented with the direct-conversion architecture.

In the transmit path, the data processor 1708 processes data to be transmitted and provides I and Q analog output signals to the transmitter 1710. In the exemplary wireless communications device 1700, the data processor 1708 includes digital-to-analog-converters (DACs) 1714(1) and 1714(2) for converting digital signals generated by the data processor 1708 into the I and Q analog output signals, e.g., I and Q output currents, for further processing.

Within the transmitter 1710, lowpass filters 1716(1), 1716(2) filter the I and Q analog output signals, respectively, to remove undesired signals caused by the prior digital-to-analog conversion. Amplifiers (AMP) 1718(1), 1718(2) amplify the signals from the lowpass filters 1716(1), 1716(2), respectively, and provide I and Q baseband signals. An upconverter 1720 upconverts the I and Q baseband signals with I and Q transmit (TX) local oscillator (LO) signals through mixers 1724(1), 1724(2) from a TX LO signal generator 1722 to provide an upconverted signal 1726. A filter 1728 filters the upconverted signal 1726 to remove undesired signals caused by the frequency upconversion as well as noise in a receive frequency band. A power amplifier (PA) 1730 amplifies the upconverted signal 1726 from the filter 1728 to obtain the desired output power level and provides a transmit RF signal. The transmit RF signal is routed through a duplexer or switch 1732 and transmitted via an antenna 1734.

In the receive path, the antenna 1734 receives signals transmitted by base stations and provides a received RF signal, which is routed through the duplexer or switch 1732 and provided to a low noise amplifier (LNA) 1736. The duplexer or switch 1732 is designed to operate with a specific RX-to-TX duplexer frequency separation, such that RX signals are isolated from TX signals. The received RF signal is amplified by the LNA 1736 and filtered by a filter 1738 to obtain a desired RF input signal. Downconversion mixers 1740(1), 1740(2) mix the output of the filter 1738 with I and Q receive (RX) LO signals (i.e., LO_I and LO_Q) from an RX LO signal generator 1742 to generate I and Q baseband signals. The I and Q baseband signals are amplified by amplifiers (AMP) 1744(1), 1744(2) and further filtered by lowpass filters 1746(1), 1746(2) to obtain I and Q analog input signals, which are provided to the data processor 1708. In this example, the data processor 1708 includes analog-to-digital-converters (ADCs) 1748(1), 1748(2) for converting the analog input signals into digital signals to be further processed by the data processor 1708.

In the wireless communications device 1700 in FIG. 17, the TX LO signal generator 1722 generates the I and Q TX LO signals used for frequency upconversion, while the RX LO signal generator 1742 generates the I and Q RX LO signals used for frequency downconversion. Each LO signal is a periodic signal with a particular fundamental frequency. A transmit (TX) phase-locked loop (PLL) circuit 1750 receives timing information from the data processor 1708 and generates a control signal used to adjust the frequency and/or phase of the TX LO signals from the TX LO signal generator 1722. Similarly, a receive (RX) phase-locked loop (PLL) circuit 1752 receives timing information from the data processor 1708 and generates a control signal used to adjust the frequency and/or phase of the RX LO signals from the RX LO signal generator 1742.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master devices and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A nanowire metal-oxide semiconductor (MOS) Field-Effect Transistor (FET) (MOSFET), comprising:
a substrate; and
a channel body disposed on the substrate, the channel body comprising:
a channel comprising a nanowire channel structure comprising a plurality of rounded nanowire structures in a stacked arrangement, each of the plurality of rounded nanowire structures comprising rounded end portions and a center portion disposed between the rounded end portions, the center portion having a greater height than the rounded end portions to form a plurality of separation areas each disposed between adjacent rounded nanowire structures among the plurality of rounded nanowire structures;
at least one dielectric material layer disposed adjacent to the plurality of rounded nanowire structures and extending into a portion of each of the plurality of separation areas disposed between the adjacent rounded nanowire structures among the plurality of rounded nanowire structures; and
a gate material disposed adjacent to the at least one dielectric material layer and extending into a portion of each of the plurality of separation areas disposed between the adjacent rounded nanowire structures among the plurality of rounded nanowire structures such that the gate material does not completely surround the plurality of rounded nanowire structures.

2. The nanowire MOSFET of claim 1, wherein the gate material is configured to create a fringing field to the channel in response to a voltage applied to the gate material.

3. The nanowire MOSFET of claim 1, further comprising at least one interfacial layer adjacent to the plurality of rounded nanowire structures between the plurality of rounded nanowire structures and the at least one dielectric material layer.

4. The nanowire MOSFET of claim 1, wherein the adjacent rounded nanowire structures among the plurality of rounded nanowire structures are not in contact with each other such that the plurality of separation areas extend completely between the adjacent rounded nanowire structures.

5. The nanowire MOSFET of claim 1, wherein:
the adjacent rounded nanowire structures among the plurality of rounded nanowire structures are not in contact with each other;
the at least one dielectric material layer comprises a plurality of dielectric materials each disposed around a rounded nanowire structure among the plurality of rounded nanowire structures; and
adjacent dielectric material layers among the plurality of dielectric materials merge together in a separation area among the plurality of separation areas disposed between the adjacent rounded nanowire structures among the plurality of rounded nanowire structures.

6. The nanowire MOSFET of claim 1, wherein the adjacent rounded nanowire structures among the plurality of rounded nanowire structures are in contact with each other such that the plurality of separation areas do not extend completely between the adjacent rounded nanowire structures.

7. The nanowire MOSFET of claim 1, wherein the plurality of rounded nanowire structures comprises a plurality of rounded nanowires.

8. The nanowire MOSFET of claim 1, wherein the plurality of rounded nanowire structures comprises a plurality of rounded nanoslabs.

9. The nanowire MOSFET of claim 1, wherein the plurality of rounded nanowire structures comprises a plurality of rounded nanosheets.

10. The nanowire MOSFET of claim 1, wherein a height of the center portion of each of the plurality of rounded nanowire structures is greater than a separation distance between a center portion of the adjacent rounded nanowire structures among the plurality of rounded nanowire structures.

11. The nanowire MOSFET of claim 1 integrated into an integrated circuit (IC).

12. The nanowire MOSFET of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

13. A nanowire metal-oxide semiconductor (MOS) Field-Effect Transistor (FET) (MOSFET), comprising:
a means for providing a channel body, comprising:
a means for providing a channel comprising a means for providing a plurality of rounded nanowire structures in a stacked arrangement, each of the means for providing the plurality of rounded nanowire structures comprising rounded end portions and a center portion disposed between the rounded end portions, the center portion having a greater height than the rounded end portions to form a plurality of separation areas each disposed between adjacent rounded nanowire structures among the plurality of rounded nanowire structures;
a means for providing a dielectric material layer adjacent to the means for providing the plurality of rounded nanowire structures, the means for providing the dielectric material layer extending into a portion of each of the plurality of separation areas; and
a means for controlling the means for providing the channel disposed adjacent to the means for providing the dielectric material layer and extending into a portion of each of the plurality of separation areas and not completely surrounding the means for providing the plurality of rounded nanowire structures.

14. A method of fabricating a nanowire metal-oxide semiconductor (MOS) Field-Effect Transistor (FET) (MOSFET), comprising:
fabricating a plurality of nanowire structures in a channel body above a substrate in a stacked arrangement;
annealing the plurality of nanowire structures to form a plurality of rounded nanowire structures forming a channel, the plurality of rounded nanowire structures creating the channel in the channel body and comprising rounded end portions and a center portion disposed between the rounded end portions, the center portion having a greater height than the rounded end portions forming a plurality of separation areas each disposed between adjacent rounded nanowire structures among the plurality of rounded nanowire structures;
disposing at least one dielectric material layer adjacent to the plurality of rounded nanowire structures and extending into a portion of each of the plurality of separation areas disposed between the adjacent rounded nanowire structures among the plurality of rounded nanowire structures; and
disposing a gate material adjacent to the at least one dielectric material layer and extending into a portion of each of the plurality of separation areas disposed between the adjacent rounded nanowire structures among the plurality of rounded nanowire structures.

15. The method of claim 14, comprising annealing the plurality of nanowire structures with hydrogen to form the plurality of rounded nanowire structures creating the channel in the channel body and comprising the rounded end portions and the center portion disposed between the rounded end portions, the center portion having the greater height than the rounded end portions.

16. The method of claim 14, further comprising disposing at least one interfacial layer around the plurality of rounded nanowire structures;
wherein disposing the at least one dielectric material layer comprises disposing the at least one dielectric material layer around the at least one interfacial layer forming the plurality of separation areas each disposed between the adjacent rounded nanowire structures among the plurality of rounded nanowire structures.

17. The method of claim 14, wherein disposing the at least one dielectric material layer further comprises merging end portions of adjacent dielectric material layers among a plurality of dielectric materials disposed around the adjacent rounded nanowire structures.

18. The method of claim 14, wherein fabricating the plurality of nanowire structures further comprises fabricating the adjacent rounded nanowire structures among the plurality of rounded nanowire structures not in contact with each other in the channel body such that the plurality of separation areas extend completely between the adjacent rounded nanowire structures.

19. The method of claim 14, wherein fabricating the plurality of nanowire structures further comprises fabricating the adjacent rounded nanowire structures among the plurality of rounded nanowire structures in contact with each other in the channel body such that the plurality of separation areas do not extend completely between the adjacent rounded nanowire structures.
